(19) United States
(12) Patent Application Publication
(10) Pub. No.: US 2025/0366003 A1
(43) Pub. Date: Nov. 27, 2025

(54) SEMICONDUCTOR DEVICE AND METHOD OF MANUFACTURING THEREOF

(71) Applicant: TAIWAN SEMICONDUCTOR MANUFACTURING COMPANY, LTD., Hsinchu (TW)

(72) Inventors: Chi-Ming HUANG, New Taipei (TW); Chun-I LIU, Hsinchu (TW); Yu-Li LIN, Kaohsiung (TW); Chih-Lun LU, New Taipei (TW); Chen-Wei PAN, Hsinchu (TW); Chih-Teng LIAO, Hsinchu (TW)

(21) Appl. No.: 19/294,297

(22) Filed: Aug. 8, 2025

Related U.S. Application Data
(62) Division of application No. 17/890,571, filed on Aug. 18, 2022.
(60) Provisional application No. 63/327,324, filed on Apr. 4, 2022.

(51) Int. Cl. H10D 30/01; H01L 21/306; H01L 21/762; H10D 64/01

(52) U.S. Cl. CPC H10D 30/024; H01L 21/30604; H01L 21/76224; H10D 64/017; H10D 64/021

(57) ABSTRACT

Some embodiments provide a process of tunning sidewall profiles of gate openings prior to filling a replacement gate electrode layer therein to improve etching rate uniformity and stability during a subsequent gate electrode etch back process. Particularly, the profile sacrificial gate electrode is adjusted to be more straight profile rather than a bowl type profile, which reduces the seam void created in the replacement gate electrode during the replacement gate process. In some embodiments, tuning the profile of gate opening further includes performing a pullback etching process of the sidewall spacers prior to depositing gate dielectric layer and work function metal layer to achieve a wider opening for metal gate filling in the replacement gate process.

### CROSS-REFERENCE TO RELATED APPLICATIONS

This application is a divisional application of U.S. patent application Ser. No. 17/890,571 filed Aug. 18, 2022, which claims priority to U.S. Provisional Application Ser. No. 63/327,324 filed Apr. 4, 2022, which is incorporated by reference in its entirety.

### BACKGROUND

The semiconductor integrated circuit (IC) industry has experienced rapid growth. Technological advances in IC materials and design have produced generations of ICs where each generation has smaller and more complex circuits than the previous generation. In the course of IC evolution, functional density (i.e., the number of interconnected devices per chip area) has generally increased while geometric size (i.e., the smallest component that can be created using a fabrication process) has decreased. Such advances have increased the complexity of manufacturing and processing ICs; similar developments in IC processing and manufacturing are being developed to meet this progress.

Along with the advantages gained from reducing geometric size, improvements are being made directly to the IC devices: for example, as metal gate CD (gate width) reduces, metal gate etching back processes may result in damages, such as semiconductor fin punch through.

### BRIEF DESCRIPTION OF THE DRAWINGS

Aspects of the present disclosure are best understood from the following detailed description when read with the accompanying figures. In accordance with standard practices within the industry, various features have not been drawn to scale. The dimensions of certain sketches may be arbitrarily increased or reduced for clarity of discussion.

FIG. 1 is a flowchart of an exemplary method for forming a semiconductor device according to embodiments of the present disclosure.

FIGS. 2-4, 5A-5C, 6A-6E, 7A-7C, 8A-8C, 9A-9C, 10A-10C, 11A-11E, 12A-12C, 13A-13C, 14A-14C, 15A-15C, 16A-16E, 17A-17D, and 18A-18D are schematic views of a semiconductor device at various stages of manufacturing said device, according to embodiments of the present disclosure.

FIGS. 19 and 20 are schematic views of a semiconductor device according to another embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The foregoing broadly outlines some aspects of embodiments described in this disclosure. While some embodiments described herein are described in the context of nanosheet channel FETs, implementations of some aspects of the present disclosure may be used in other processes and/or in other devices, such as planar FETs, Fin-FETs, Horizontal Gate All Around (HGAA) FETs, Vertical Gate All Around (VGAA) FETs, and other suitable devices. A person having ordinary skill in the art will readily understand other modifications that may be made are contemplated within the scope of this disclosure. In addition, although method embodiments may be described in a particular order, various other method embodiments may be performed in any logical order and may include fewer or more steps than what is described herein. In the present disclosure, a source/drain region(s) may refer to a source or a drain, individually or collectively dependent upon the context.

Embodiments of the disclosure provide methods for adjusting profiles of sacrificial gate structures (also known as dummy gates, and commonly referred to as poly) and the semiconductor device formed thereof. Some embodiments provide a process of tuning sidewall profiles of gate openings prior to filling a replacement gate electrode layer therein to improve etching rate uniformity and stability during a subsequent gate electrode etch back process. In some embodiments, tuning the profile of gate opening includes adjusting the profile of a sacrificial gate electrode during formation of the sacrificial gate formation. Particularly, the profile sacrificial gate electrode is adjusted to be more straight profile rather than a bowl type profile, which reduces the seam void created in the replacement gate electrode during the replacement gate process. In some embodiments, tuning the profile of gate opening further includes performing a pullback etching process of the sidewall spacers prior to depositing the work function metal layer to achieve a wider opening for metal gate filling in the replacement gate process. Embodiments of the present disclosure avoid fin damages that may occur during the metal gate etch back and short circuits between gate electrodes and neighboring source/drain contacts.

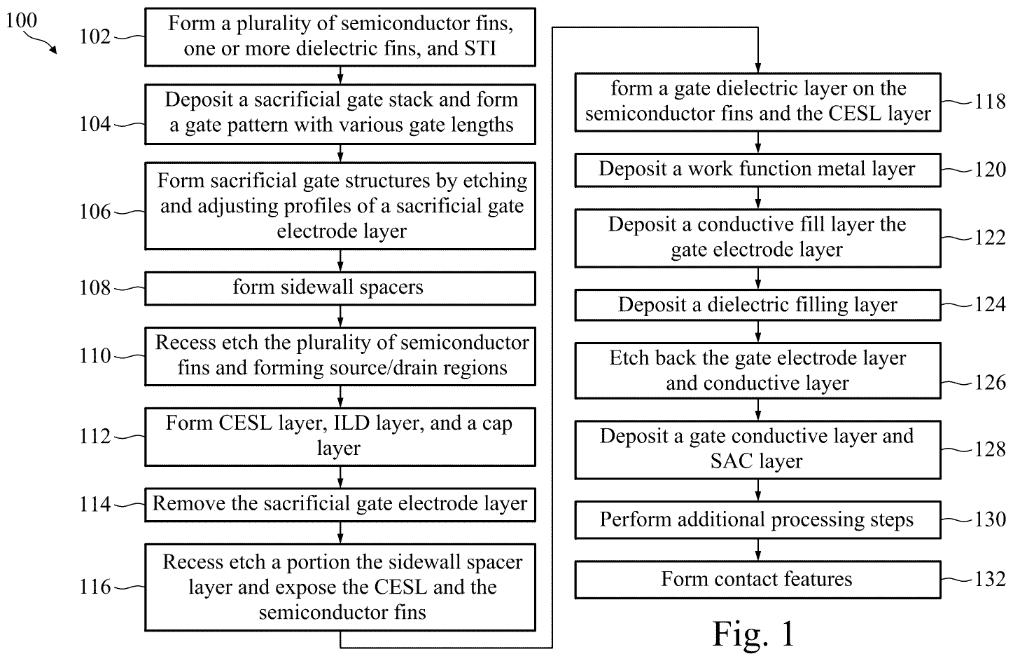

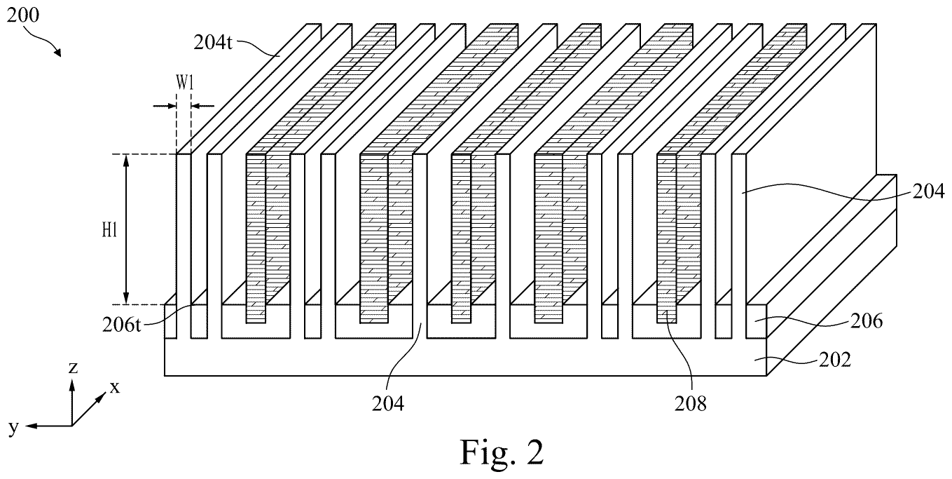

FIG. 1 is a flow chart of an exemplary method 100 for forming a semiconductor device according to embodiments of the present disclosure. FIGS. 2-4, 5A-5C, 6A-6E, 7A-7C, 8A-8C, 9A-9C, 10A-10C, 11A-11E, 12A-12C, 13A-13C, 14A-14C, 15A-15C, 16A-16E, 17A-17D, and 18A-18D schematically illustrate a semiconductor device 200 at various stages of fabrication according to the method 100.

The method 100 begins at operation 102, a plurality of semiconductor fins 104 on a substrate 202, the plurality of semiconductor fins 204 extending above a STI (shallow trench isolation) layer 206 as shown in FIG. 2. FIG. 2 is a schematic perspective view of the semiconductor device 200 after operation 102.

The substrate 202 may include a single crystalline semiconductor material such as, but not limited to Si, Ge, SiGe, GaAs, InSb, GaP, GaSb, InAlAs, InGaAs, GaSbP, GaAsSb, and InP. The substrate 202 may include various doping configurations depending on circuit design. For example, the substrate 202 may have one or more p-doped regions and one or more n-doped regions. In some embodiments, the substrate 202 is a silicon (100) substrate. The plurality of semiconductor fins 204 are then formed using one or more patterning and etching processes. The STI layer 206 is formed in the trenches between the plurality of semiconductor fins 204 by a suitable deposition followed by an etch back process. The bottom profile of the STI layer 206 is shown to be planar as an example. Depending on pitch and/or height of the semiconductor fins 204, a bottom profile of the STI layer 206 may vary, for example curved, substantially flat, or other shapes. The STI layer 206 may be formed by a high-density plasma chemical vapor deposition (HDP-CVD), a flowable CVD (FCVD), or other suitable deposition process. In some embodiments, the STI layer 206 may include silicon oxide, silicon nitride, silicon oxynitride, fluorine-doped silicate glass (FSG), a low-k dielectric, combinations thereof. In some embodiments, the STI layer 206 is formed to cover the plurality of semiconductor fins 204 by a suitable deposition process to fill the trenches between the plurality of semiconductor fins 204, a planarization process may be performed to expose the plurality of semiconductor fins 204, and then recess etched using a suitable anisotropic etching process to expose a portion of the plurality of semiconductor fins 204.

In FIG. 2, the semiconductor fins 204 are formed along the X direction. A width W1 of the semiconductor fins 204 along the Y direction is in a range between about 10 nm and about 40 nm. In some embodiments, the width W1 of the semiconductor fins 30 along the Y direction is in a range between about 20 nm and about 30 nm. In some embodiments, a top surface 204t of the semiconductor fins 204 have a height H1 over a top surface 206t of the STI layer 206 along the Z direction. The height H1 may vary according to circuit design. In some embodiments, the height H1 is in a range between about 20 nm to about 100 nm.

The plurality of semiconductor fins 204 may be positioned at various distances along the Y direction. In some embodiments, one or more dielectric fins 208 may be formed between the plurality of semiconductor fins 204. The dielectric fins 208 are designed to electrically isolate devices subsequently formed from the semiconductor fins 204 on either side of the dielectric fin 208. In some embodiments, the dielectric fin 208 may prevent undesirable lateral merging of source/drain epitaxial features formed on adjacent semiconductor fins 204.

In some embodiments may be formed by forming a conformal isolation material between the plurality of semiconductor fins 204 resulting in trenches between neighboring semiconductor fins 204. The trenches are subsequently filled with one or more dielectric layers to form the dielectric fins 208 therein. After the formation of the dielectric fins 208, a planarization process, such as a chemical mechanical polishing (CMP) process, is performed to remove the excessive isolation material and dielectric fins 208 until the plurality of semiconductor fins 204 are exposed. The isolation layer is then etched back to form the STI layer 206 with the plurality of semiconductor fins 204 and one or more dielectric fins 208 extending therefrom, as shown in FIG. 2.

In some embodiments, the dielectric fins 208, also referred to as dummy fins or hybrid fins, may include a high-k dielectric material layer, a low-k dielectric material layer, or a bi-layer dielectric material including high-k upper part and a low-k lower part. In some embodiments, the dielectric fins 208 include a high-k metal oxide, such as HfO₂, ZrO₂, HfAlOₓ, HfSiOₓ, Al₂O₃, and the like, a low-k material such as SiONC, SiCN, SiOC, or other dielectric material.

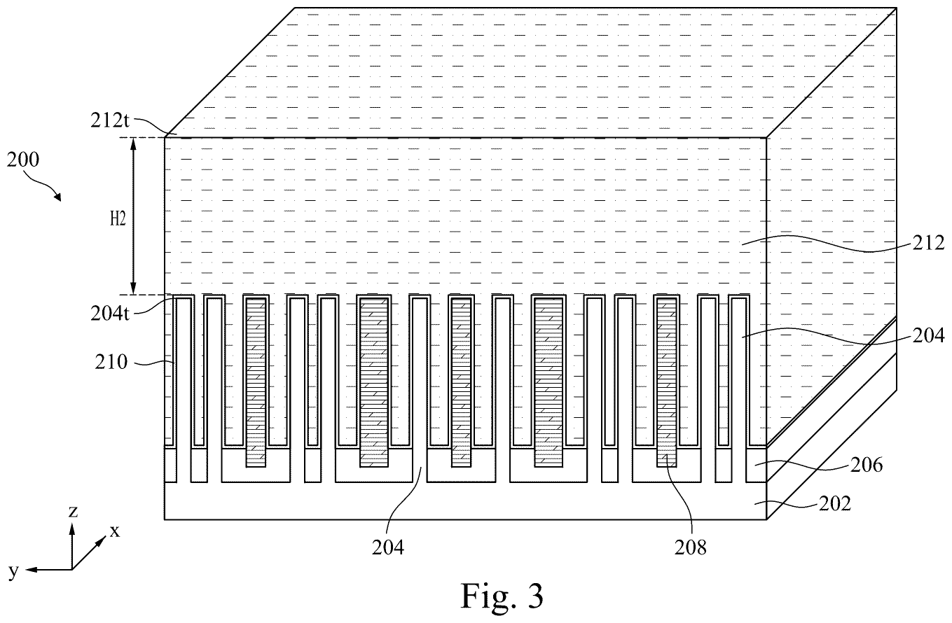

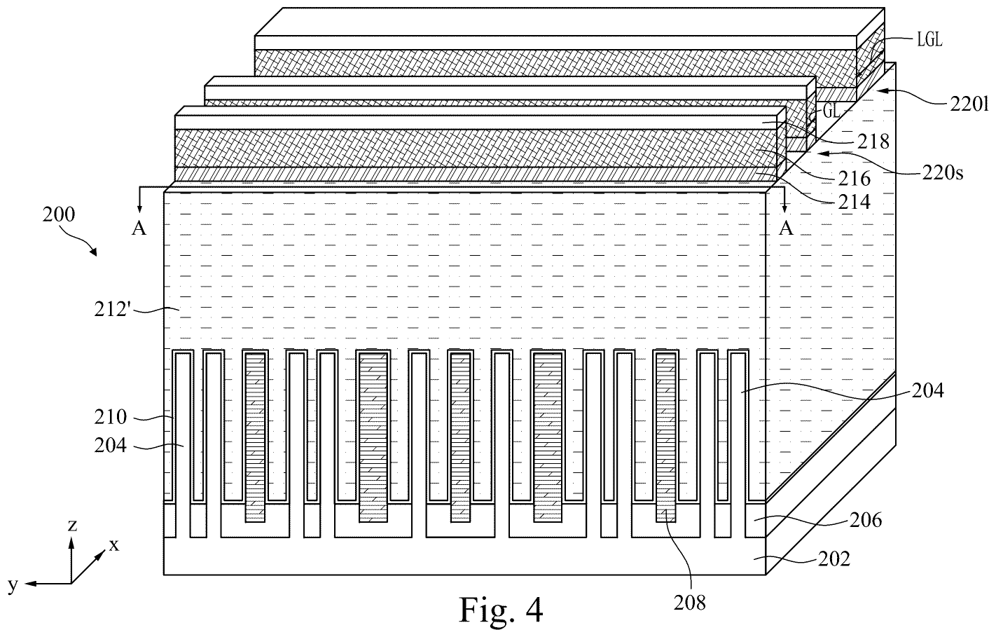

At operation 104, a sacrificial gate stack in deposited and a gate pattern with various gate lengths is formed as shown in FIGS. 3 and 4. FIG. 3 is a schematic perspective view of the semiconductor device 200 after a sacrificial gate dielectric layer 210 and a sacrificial gate electrode layer 212′ are formed over the semiconductor fins 204.

The sacrificial gate dielectric layer 210 is conformally over the substrate 202. The sacrificial gate dielectric layer 210 is formed over the semiconductor fins 204 and the dielectric fins 208. The sacrificial gate dielectric layer 210 covers the semiconductor fins 204. The sacrificial gate dielectric layer 210 is configured to cover and protect the semiconductor fins 204 during the subsequent etching processes to form sacrificial gate stacks.

The sacrificial gate dielectric layer 210 and the sacrificial gate electrode layer 212′, which is subsequently deposited, may include sufficient etching selectivity of the etching process, such that the sacrificial gate dielectric layer 210 remains after etching the sacrificial gate electrode layer 212′. That is, the sacrificial gate dielectric layer 210 may include higher etching resistance to the etchant than the sacrificial gate electrode layer 212′. In some embodiments, the sacrificial gate dielectric layer 210 has a thickness in a range between about 1 nm and about 4 nm. The sacrificial gate dielectric layer 210 may include silicon oxide, silicon nitride, a combination thereof, or the like. The sacrificial gate dielectric layer 210 may be deposited or thermally grown according to acceptable techniques, such as thermal CVD, CVD, ALD, and other suitable methods.

The sacrificial gate electrode layer 212′ is then deposited on the sacrificial gate dielectric layer 210 and then planarized, such as with a CMP process. The sacrificial gate electrode layer 212′ includes silicon such as polycrystalline silicon, amorphous silicon, poly-crystalline silicon-germanium (poly-SiGe), or the likes. The sacrificial gate electrode layer 212′ may be deposited using CVD, including LPCVD and PECVD, PVD, ALD, or other suitable process. In some embodiments, the sacrificial gate electrode layer 212′ is subjected to a planarization operation.

After the planarization operation, a top surface 212t of the sacrificial gate electrode layer 212′ may have a height H2 from the top surface 204t of the semiconductor fins 204. In some embodiment, the height H2 is in a range between about 100 nm and about 200 nm.

FIG. 4 is a schematic perspective view of the semiconductor device 200 after a gate mask stack 220 is then formed and patterned over the top surface 212t of the sacrificial gate electrode layer 212′. The gate mask stack 220 is used during processing to form features in the sacrificial gate electrode layer 212′. The gate mask stack 220 may include an ARC (anti-reflective coating) 214, a mask layer 216, and a mandrel layer 218. The ARC 214 is deposited on the sacrificial gate electrode layer 212′. The ARC 214 may be formed be formed from SiON, SiC, materials doped with oxygen (O) and nitrogen (N), or the like. In some embodiments, the ARC 214 is substantially free from nitrogen, and may be formed from an oxide. In some embodiments, the ARC 214 may be formed having a thickness between about 15 nm and about 25 nm.

The mask layer 216 is deposited over the ARC 214. The mask layer 216 may be formed of a material selected be formed of a hard masking material, and may include a metal and/or a dielectric material. In some embodiments, the mask layer 216 includes a metal such as titanium nitride, titanium, tantalum nitride, tantalum, or the like. In some embodiments, the mask layer 216 includes a dielectric formed of an oxide, a nitride, or the like. The mask layer 216 may be formed by PVD, Radio Frequency PVD (RFPVD), Atomic Layer Deposition (ALD), or the like. In some embodiments, the mask layer 216 may be formed having a thickness between about 90 nm and about 110 nm.

The mandrel layer 218 is deposited over the mask layer 216. The mandrel layer 218 may be formed of a material that has a high etching selectivity with the underlying layer, e.g., with the mask layer 216. The mandrel layer 218 may be formed of a material such as amorphous silicon, polysilicon, silicon nitride, silicon oxide, the like, or a combination thereof, and may be formed using a process such as a chemical vapor deposition (CVD), PECVD, or the like. In some embodiments, the mandrel layer 218 may be formed having a thickness between about 90 nm and about 110 nm.

In FIG. 4, the gate mask stack 220 is patterned to form one or more gate masks of various gate lengths, such as gate masks 220s, 220l, using any suitable photolithography technique. In the example shown in FIG. 4, the gate mask 220s has a shorter gate length GL while the gate mask 220l has a longer gate length LGL. In some embodiments, the gate length GL may be in a range between about 10 nm and 20 nm. The long gate length LGL may be in a range between about 20 nm and 100 nm.

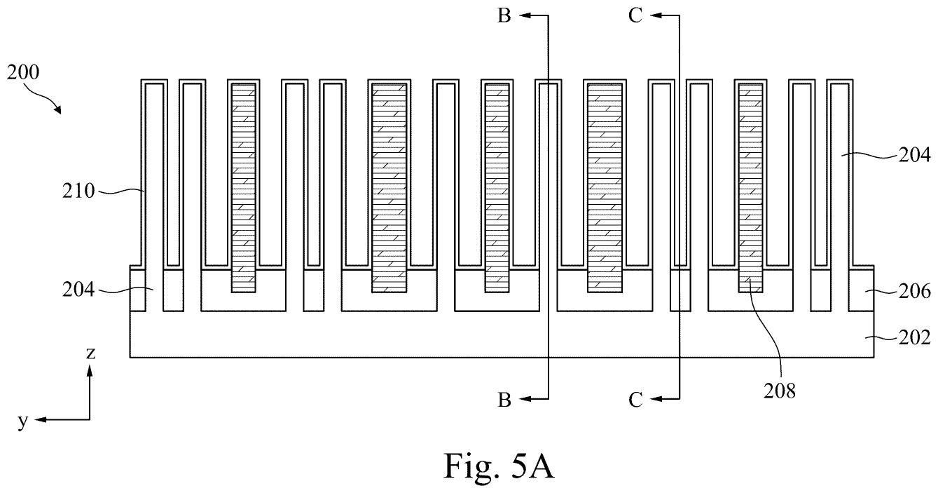

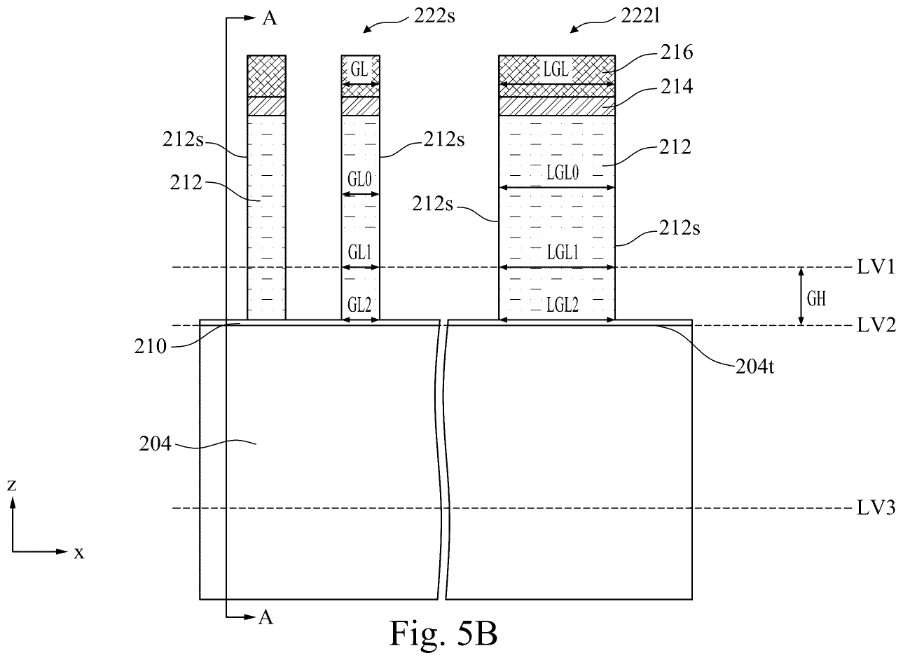

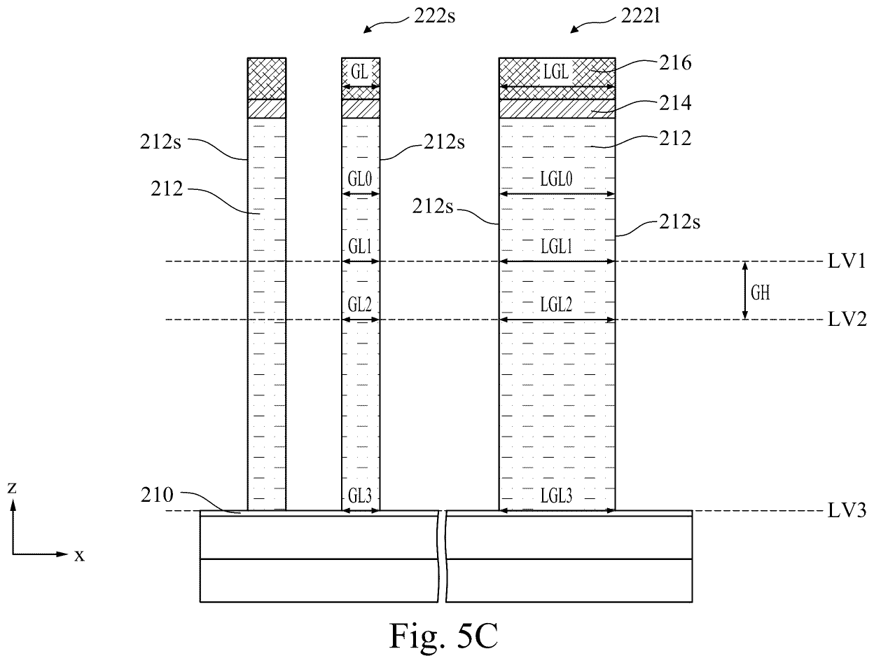

At operation 106, the gate electrode layer 212′ is etched using the gate masks 220s, 220l to form sacrificial gate electrode 212, as shown in FIGS. 5A-5C. FIG. 5A is a schematic cross-sectional view of the semiconductor device 200 along the Y direction across line A-A in FIG. 5B. FIGS. 5B and 5C are schematic cross sectional views of the semiconductor device 200 along lines B-B, C-C in FIG. 5A respectively. One or more etching processes may be performed to form the sacrificial gate electrodes 212 from the sacrificial gate electrode layer 212′. The sacrificial gate electrode layer 210 may serve as an etch stop to protect the semiconductor fins 204 during the etch processes.

In some embodiments, process parameters of the etch processes may be configured to achieve a desired profile for the sacrificial gate electrode 212. In some embodiments, the profile of the sacrificial gate electrode 212 may be controlled by controlling and adjusting parameters of the etching process to obtain a desired gate length GL at particularly vertical level along the Z direction.

In some embodiments, one or more anisotropic etch processes, such as a reactive ion etching (RIE) process, may be performed to form the sacrificial gate electrodes 212. Process gases may be activated into plasma by any suitable method of generating the plasma, such as transformer coupled plasma (TCP) systems, inductively coupled plasma (ICP) systems, magnetically enhanced reactive ion techniques, electron cyclotron resonance techniques, or the like. The plasma generation power or the bias voltage may be pulsed as a rectangular wave or a square wave, though other pulse shapes may be used. In some embodiments, the plasma generation power and the bias voltage may have synchronized pulses, such that the plasma generation power and the bias voltage are simultaneously in their respective low state or high state. In some embodiments, the plasma is a direct plasma. In other embodiments, the plasma is a remote plasma that is generated in a separate plasma generation chamber connected to the processing chamber.

The process gasses used in the etching processes may include etchant gasses such as CF4, CHF3, Cl2, H2, N2, Ar, or a combination of gasses. In some embodiments, process gasses also include passivation gasses, such as HBr, O2, or a combination of gasses. In some embodiments, a carrier gas, such as N2, Ar, He, or the like, may be used to carry process gasses into a processing chamber during the etching process.

In some embodiments, the profile shape of the sacrificial gate electrodes 212 may be controlled by controlling the flow rate of passivation gasses into the processing chamber during the etching process. For example, the gate length GL may be increased by increasing the flow rate of the passivation gasses. In some embodiments, the profile shape of the sacrificial gate electrodes 212 may be controlled by controlling the duty cycle of synchronized plasma generation power and bias voltage pulses. For example, increasing the duty cycle of the synchronized pulses may cause an increase in the gate length GL. By controlling the flow rate of the passivation gasses and the duty cycle of the synchronized pulses, the profile and width of the sacrificial gate electrodes 212 may be controlled.

In some embodiments, multiple plasma etching processes may be used to tune gate lengths at different levels of the sacrificial gate electrode 212. LV1 in FIGS. 5B and 5C is at a height GH above the top surface 204t of the semiconductor fins 204. LV2 is at the top surface 204t of the semiconductor fins 204. LV3 is slightly above the top surface 206t of the STI layer 206. The height GH corresponds to a height of gate electrode to be remained in the resulting semiconductor device 200. In some embodiments, the height GH is between about 30 nm and 60 nm. The resulting sacrificial gate electrode 212ss, 212l have gate lengths GL1/GL2/GL3 and LGL1/LGL2/LGL3 at the levels LV1/LV2/LV3.

In some embodiments, a first etching process may be performed to etch the sacrificial gate electrodes layer 212′ between the top surface 212t and the level LV2, a second etching process may be performed to etch the sacrificial gate electrodes layer 212′ between the level LV2 and the level LV3, and a third etching process may be performed to over etch, remove residue, and fine tuning the profiles.

In some embodiments, the first etching process may be performed using a process gas mixture including etchant gasses such as CF4, CHF3, Cl2, H2, N2, Ar, or a combination of gasses, passivation gasses such as HBr, O2, other gasses, or a combination of gasses, and carrier gasses, such as N2, Ar, He, or the like. The process gas mixture may be flown into the processing chamber at a rate between about 300 sccm and about 400 sccm. For example, the etchant gasses may be flown into the processing chamber at a rate between about 30 sccm and about 50 sccm, and the passivation gasses may be flown into the processing chamber at a rate between about 200 sccm and about 300 sccm. In some embodiments, the passivation gasses may be a mixture of HBr and O2, in which the ratio of HBr:O2 is between about 3:1 and about 5:1. The first etching process may be performed using a bias voltage having a high voltage between about 600 volts and about 700 volts. The first etching process may be performed using a plasma generation power having a high power between about 1000 Watts and about 1500 Watts. In some embodiments, the plasma generation power or the bias voltage may be pulsed having a duty cycle between about 2% and about 8%, and may have a pulse frequency between about 100 Hz and about 200 Hz. The first etching process may be performed at a temperature between about 38° C. and about 43° C. A pressure in the processing chamber may be between about 20 mTorr and about 30 mTorr.

In some embodiments, the second etching process may use a process gas mixture including etchant gasses such as CF4, Cl2, H2, N2, Ar, other gasses, or a combination of gasses, passivation gasses such as HBr, O2, other gasses, or a combination of gasses, and carrier gasses, such as N2, Ar, He, or the like. The process gas mixture may be flown into the processing chamber at a rate between about 120 sccm and about 250 sccm. The second etching process may be performed using a bias voltage, having a low voltage between about 600 volts and about 700 volts and having a high voltage between about 800 volts and about 900 volts. The second etching process may be performed using a substantially constant plasma generation power between about 500 Watts and about 700 Watts. In some embodiments, the bias voltage may be pulsed having a duty cycle between about 5% and about 8%, and may have a pulse frequency between about 100 Hz and about 300 Hz. The second etching process may be performed at a temperature between about 34° C. and about 50° C. A pressure in the processing chamber may be between about 70 mTorr and about 90 mTorr.

In some embodiments, the third etching process may use a process gas mixture including etchant gasses such as CF4, Cl2, H2, N2, Ar, other gasses, or a combination of gasses, passivation gasses such as HBr, O2, other gasses, or a combination of gasses, and carrier gasses, such as N2, Ar, He, or the like. The process gasses may be flown into the processing chamber at a rate between about 400 sccm and about 550 sccm. For example, the etchant gasses may be flown into the processing chamber at a rate between about 130 sccm and about 210 sccm, and the passivation gasses may be flown into the processing chamber at a rate between about 200 sccm and about 250 sccm. In some embodiments, the passivation gasses may be a mixture of HBr and O2, in which the ratio of HBr:O2 is between about 3:1 and about 4:1. The third etching process may be performed using a bias voltage having a low voltage between about 850 volts and about 900 volts and having a high voltage between about 900 volts and about 950 volts. The third etching process may be performed using a substantially constant plasma generation power between about 250 Watts and about 350 Watts. In some embodiments, the bias voltage may be pulsed having a duty cycle between about 10% and about 20%, and may have a pulse frequency between about 100 Hz and about 200 Hz. The third etching process may be performed at a temperature between about 40° C. and about 50° C. A pressure in the processing chamber may be between about 70 mTorr and about 90 mTorr.

In some embodiments, the profile of the sacrificial gate electrode 212 may be substantially straight. For example, the gate length GL1 is substantially the same as the gate length GL2. In some embodiments, a ratio of the gate length GL1 over gate length GL2 is less than 1.0, for example, in a range between about 0.9 and 1.0. In some embodiments, the difference between the gate length GL1 and the gate length GL2 is less than about 2.0 nm.

After operation 106, sacrificial gate structures 222s, 222l (collectively 222) are formed. The sacrificial gate structures 222s, 222l have different gate lengths. The sacrificial gate structures 222 cover a portion of the semiconductor fins 204 and the dielectric fins 208. The portion of the semiconductor fins 204 covered by the sacrificial gate structures 222 eventually form a channel region, including one or more channels in the FinFET device. After operation 106, the sacrificial dielectric layer 210 may still remain on the top surface 204t and sidewalls of the semiconductor fins 204. In some embodiments, an etching process may be performed to remove the exposed portion of the sacrificial gate dielectric layer 210. In other embodiments, portions of the sacrificial gate dielectric layer 210 may be removed during formation of sidewall spacers.

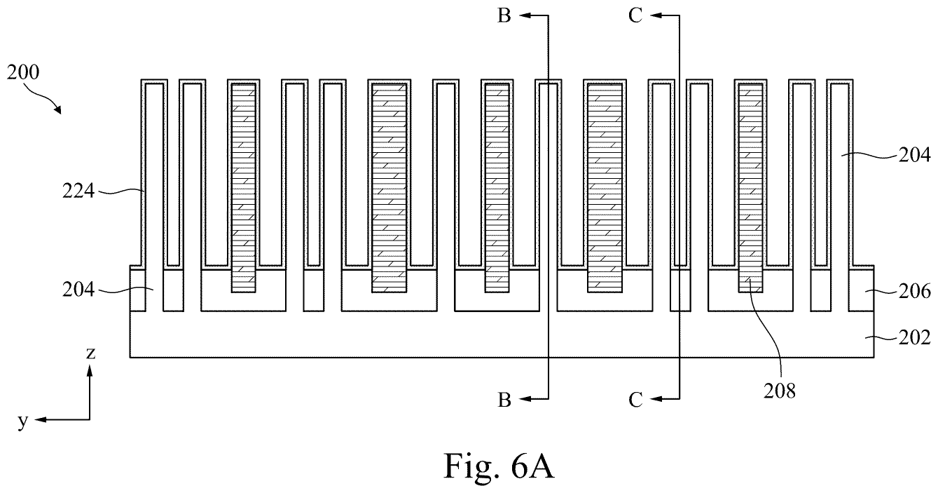

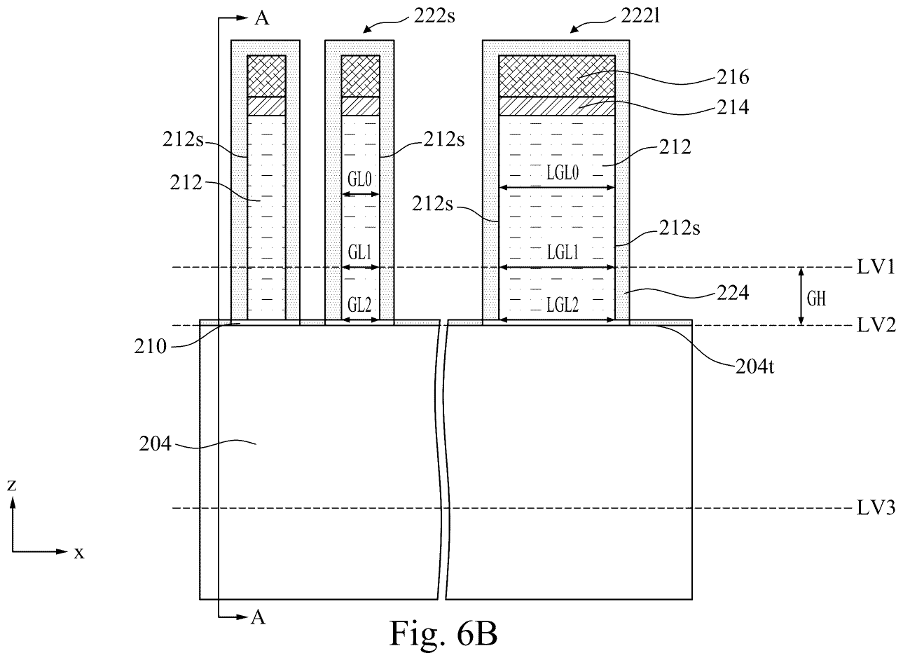

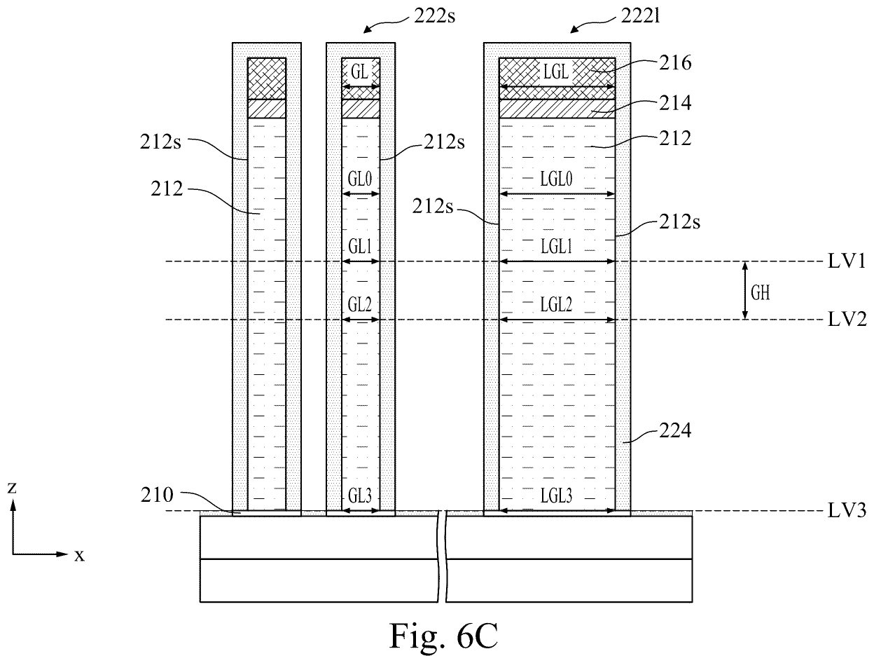

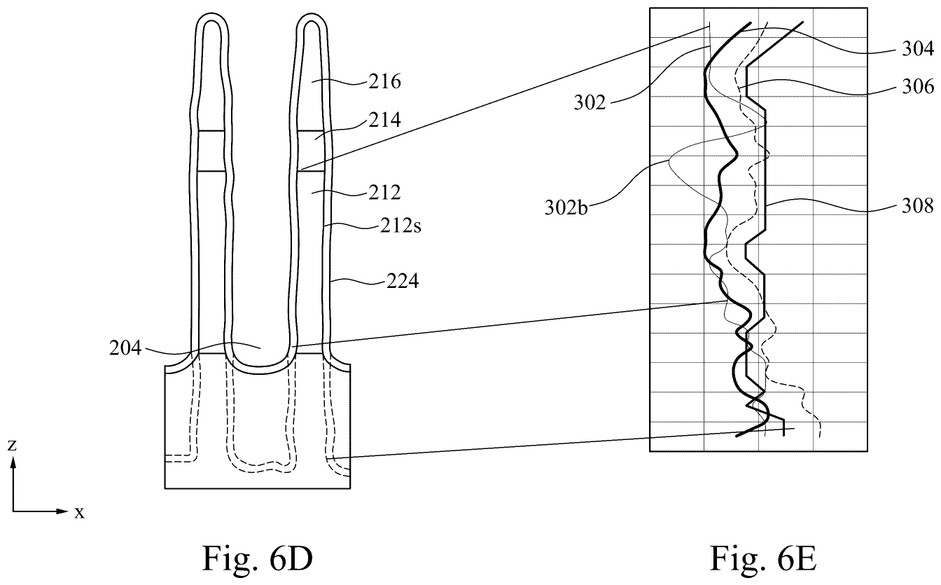

At operation 108, sidewall spacers 224 may be formed on the sacrificial gate stacks 222, as shown in FIGS. 6A-6C. FIG. 6A is a schematic cross-sectional view of the semiconductor device 200 along the Y direction across line A-A in FIG. 6B. FIGS. 6B and 6C are schematic cross-sectional views of the semiconductor device 200 along lines B-B, C-C in FIG. 6A respectively.

A dielectric material may be conformally formed on exposed surfaces of the sacrificial gate structures 222, the STI layer 206, the semiconductor fins 204, and the dielectric fins 208. The dielectric materials may be formed by a thermal oxidation process or a deposition process. An anisotropic etching process may be followed to remove the dielectric material from horizontal surfaces to form the sidewall spacers 224.

In some embodiments, the sidewall spacers 224 may have a thickness T1. In some embodiments, the thickness T1 may be in a range between about 2 nm and about 10 nm. In some embodiments, the sidewall spacers 224 may be formed from a low-k dielectric material, such as a silicon oxide. In some embodiments, the sidewall spacers 224 a silicon nitride-based material, such as SiN, SiON, SiOCN or SiCN and combinations thereof.

FIG. 6D includes outlines traced from a transmission electron microscope (TEM) image of a semiconductor device similar to the semiconductor device 200. As demonstrated in FIG. 6D, the sidewall 212s of the sacrificial gate electrode 212 has a substantially straight profile along the Z direction.

FIG. 6E includes profiles of sidewalls of sacrificial gate electrodes. Curve 302 is a sidewall profile of a sacrificial gate electrode according to current technology. Curve 302 includes a bowled portion 302b above the top surface 204t of the semiconductor fins 204. In some embodiments, the bowled portion 302b may extend outward for about 5 nm from the remaining portion of the sacrificial gate electrode. The bowled portion 302b may lead to a seam or a void in the subsequently formed replacement gate electrode. Curves 304, 306, 308 are profiles of sacrificial gate electrode 212 according to the present disclosure. The curves 304, 306, 308 are substantially straight.

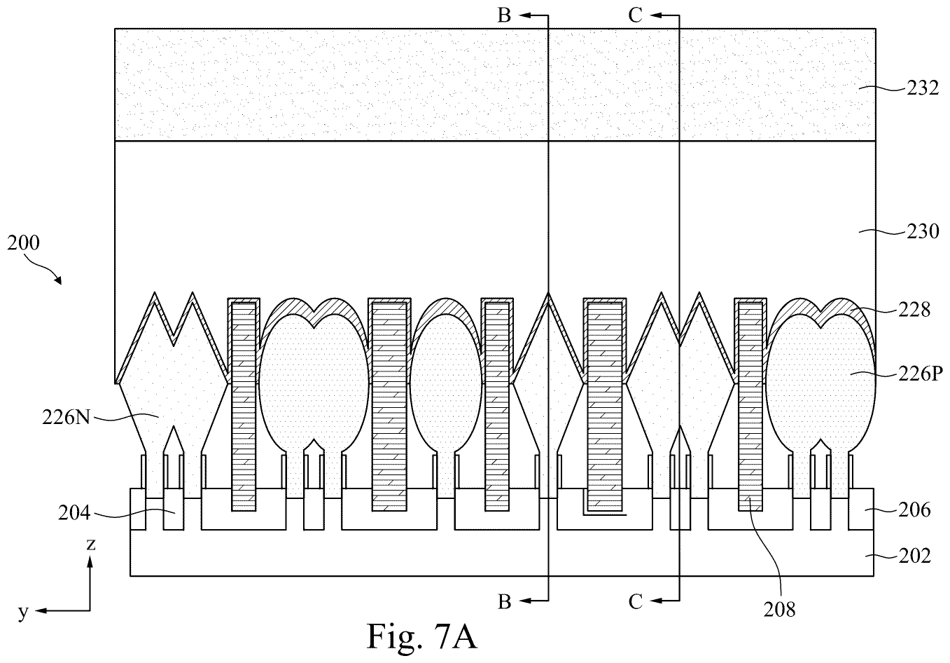

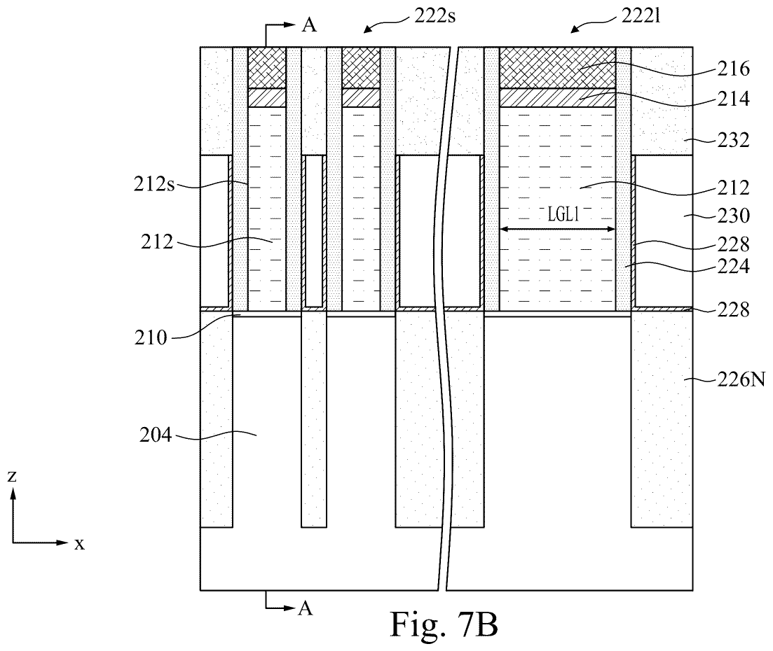

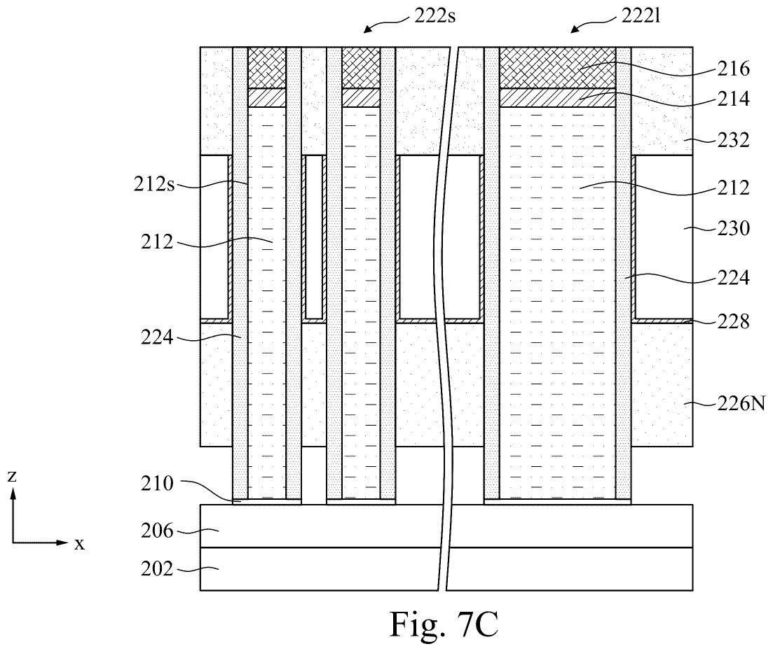

At operation 110, as shown in FIGS. 7A-7C, the semiconductor fins 204 on opposite sides of the sacrificial gate structure 222 are recess etched and source/drain regions 226P, 226N (collective 226) are formed. FIG. 7A is a schematic cross-sectional view of the semiconductor device 200 along the Y direction across line A-A in FIG. 7B. FIGS. 7B and 7C are schematic cross-sectional views of the semiconductor device 200 along lines B-B, C-C in FIG. 7A respectively.

The semiconductor fins 204 are etched down on both sides of the sacrificial gate structure 222 using one or more lithography and etching operations. In some embodiments, suitable dry etching and/or wet etching may be used to remove the semiconductor fins 204. In some embodiments, the semiconductor fins 204 may be recess etched below the top surface 206t of the STI layer 206. In some embodiments, portions of the sidewall spacers 224 may remain on the STI layer 206.

Source/drain regions 226 are then formed. In some embodiments, the source/drain regions 226 may be formed from the exposed surfaces of the semiconductor fins 204 by epitaxial growth. The source/drain regions 226 may be formed by an epitaxial growth method using CVD, ALD or molecular beam epitaxy (MBE). The source/drain regions 226N are formed in n-type device areas and the source/drain regions 226P are formed in p-type device areas. The source/drain regions 226N may include one or more layers of Si, SiP, SiC and SiCP for NFET. The source/drain regions 226P may include Si, SiGe, Ge. The source/drain regions 226N and the source/drain regions 226P may be formed in separate processes using suitable masks.

At operation 112, as shown in FIGS. 7A-7C, a contact etch stop layer (CESL) 228 and an interlayer dielectric (ILD) layer 230 are formed over the substrate 202. The CESL 228 is formed on the epitaxial source/drain features 60. In some embodiments, the CESL 228 has a thickness in a range between about 1 nm and about 15 nm. The CESL 228 may include Si₃N₄, SiON, SiCN or any other suitable material, and may be formed by CVD, PVD, or ALD.

The ILD layer 230 is formed over the CESL 228. The materials for the ILD layer 230 may include compounds comprising Si, O, C, and/or H, such as silicon oxide, SiCOH and SiOC. Organic materials, such as polymers, may be used for the ILD layer 230.

In some embodiments, an etching process may be performed to remove portions of the ILD layer 230 to form recesses. A cap dielectric layer 232 is then deposited in the recesses. The cap dielectric layer 232 may be formed from a material with high etch selectivity relative to the sidewall spacers 224 to protect the ILD layer 230 during subsequent replacement gate process.

The cap dielectric layer 232 may be formed using a suitable deposition process, such as ALD, CVD, etc. In some embodiments, the cap dielectric layer 232 may include yttrium silicon oxide (YSiOₓ). In other embodiments, the cap dielectric layer 232 may include silicon nitride (SiN), silicon oxy-carbide (SiOC), silicon carbon nitride (SiCN), or silicon oxy-carbon nitride (SiOCN).

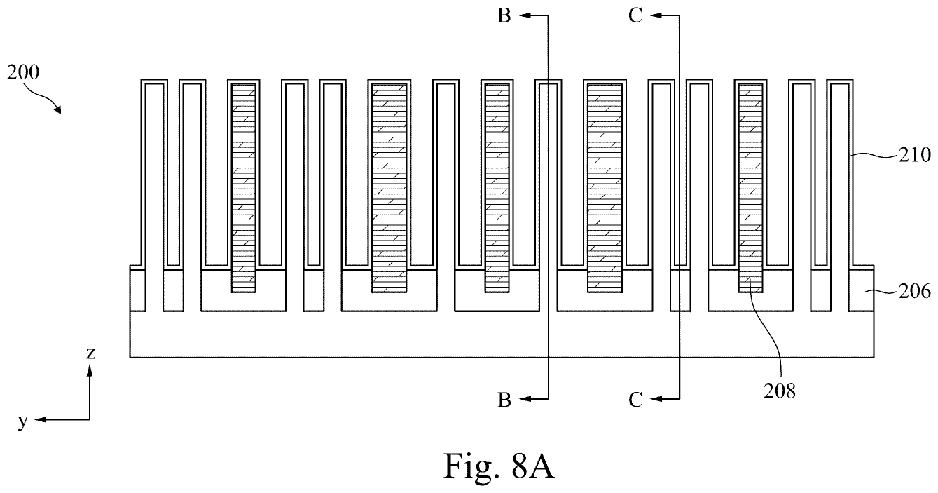

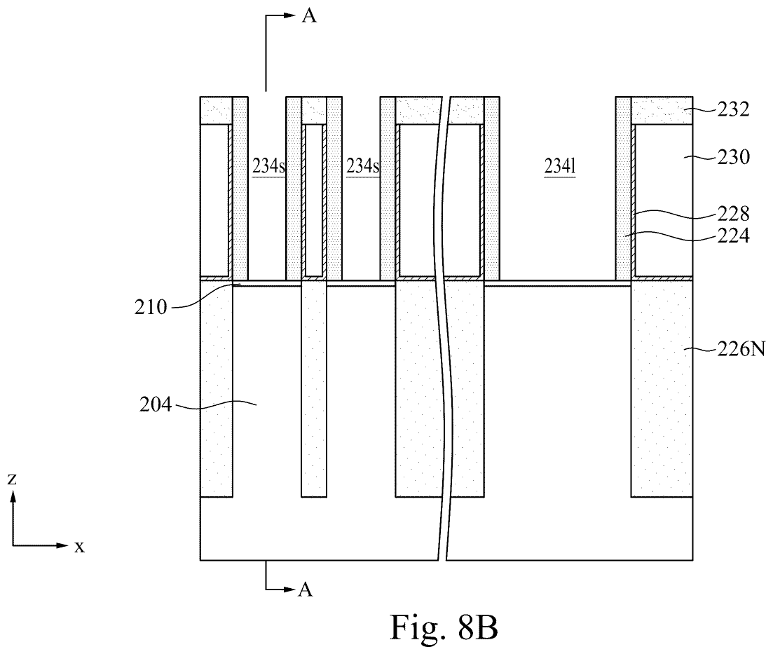

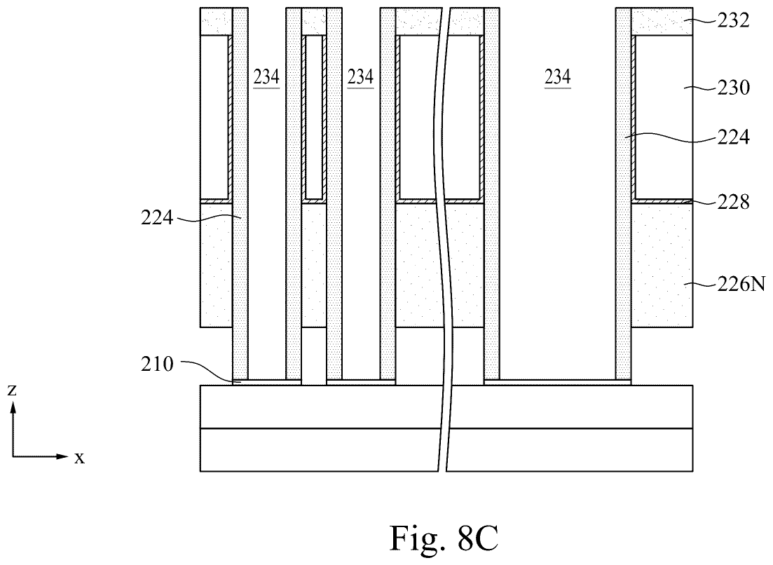

At operation 114, the sacrificial gate electrodes 212 are removed to form gate cavities 234, as shown in FIGS. 8A-8C. FIG. 8A is a schematic cross-sectional view of the semiconductor device 200 along the Y direction across line A-A in FIG. 8B. FIGS. 8B and 8C are schematic cross-sectional views of the semiconductor device 200 along lines B-B, C-C in FIG. 8A respectively.

Following the deposition of the cap dielectric layer 232, a planarization process such as a CMP process may be performed to polish the surface of the cap dielectric layer 232, until the sacrificial gate electrode 212 is exposed. In some embodiments, after the planarization, the cap dielectric layer 232 has a thickness along the z direction in a range between about 15 nm and about 30 nm.

The sacrificial gate electrodes 212 may be removed by using plasma dry etching and/or wet etching. In some embodiments, a wet etchant such as a tetramethylammonium hydroxide (TMAH) solution can be used to selectively remove the sacrificial gate electrode 212 without removing the dielectric materials of the cap dielectric layer 232 and the sidewall spacers 224. At this stage, the gate cavities 234 are defined by the sidewall spacers 224 and the sacrificial gate dielectric layer 210.

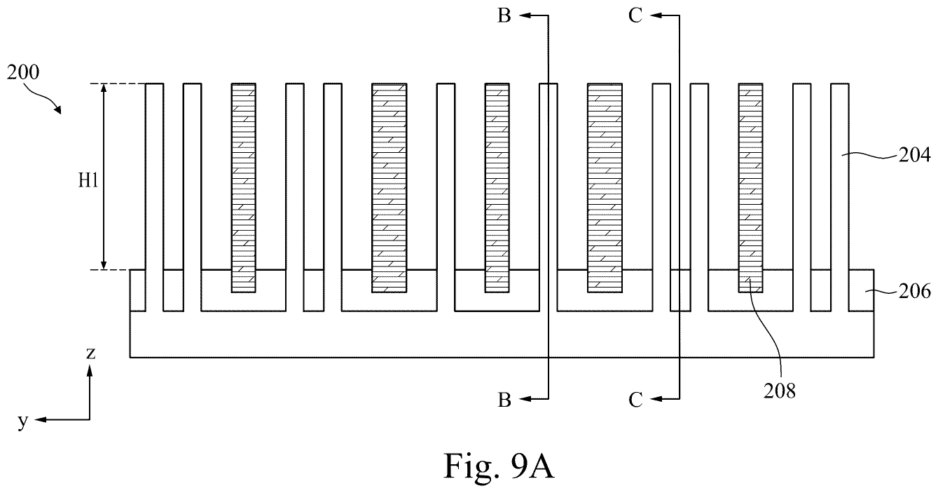

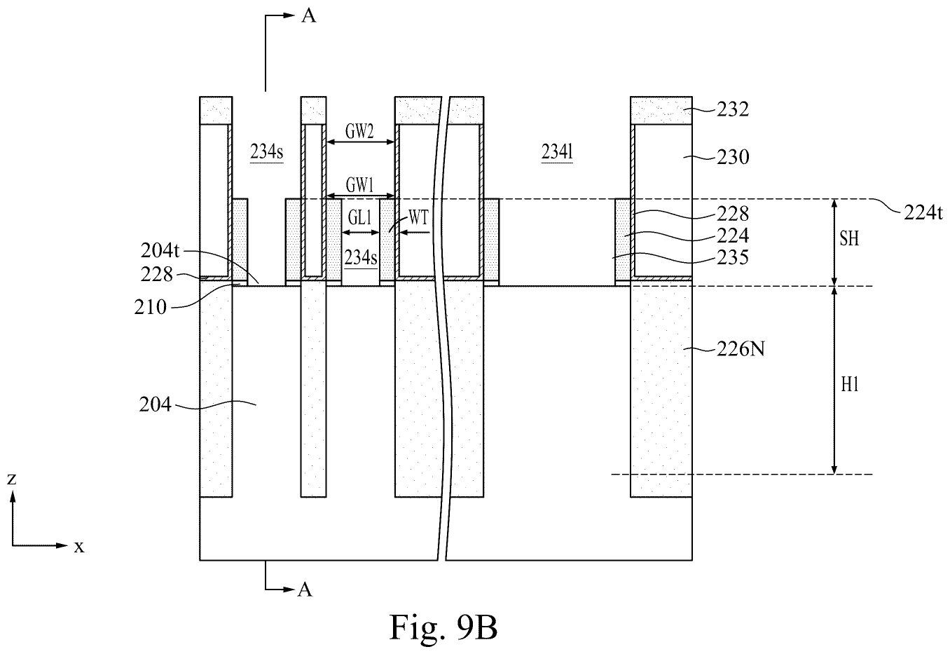

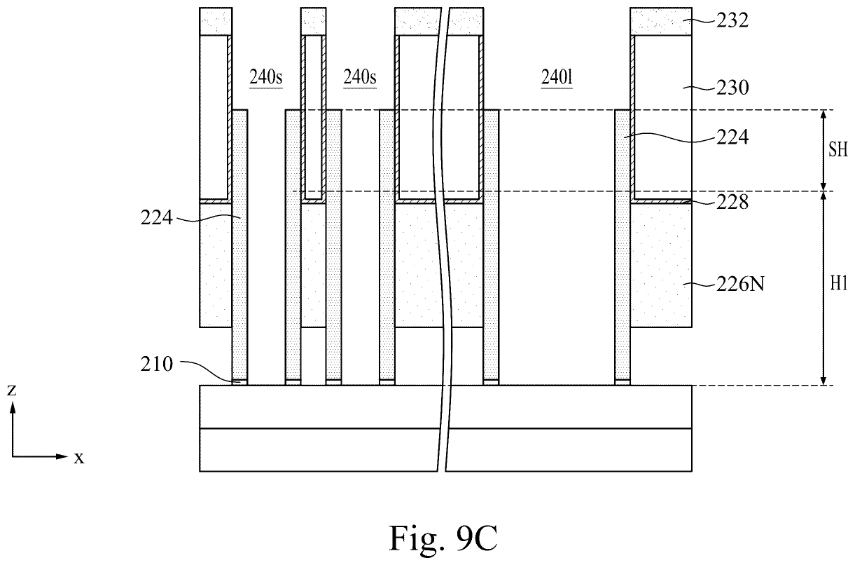

At operation 116, the sidewall spacers 224 are etched to pullback as shown in FIGS. 9A-9C. FIG. 9A is a schematic cross-sectional view of the semiconductor device 200 along the Y direction across line A-A in FIG. 9B. FIGS. 9B and 9C are schematic cross-sectional views of the semiconductor device 200 along lines B-B, C-C in FIG. 9A respectively.

An etching process is performed to pull-back the sidewall spacers 224. In some embodiments, an anisotropic etch process is used to selectively remove top portions of the sidewall spacers 224. In some embodiments, a plasma etch process may be used.

As shown in FIGS. 9B-9C, the sidewall spacers 224 is selectively etched from the CESL 228. After the pull-back process, a top surface 224t of the sidewall spacers 224 is at a height SH above the top surface 204t of the semiconductor fins 204. The height SH is selected to provide isolation between subsequently formed gate electrode structure and source/drain contact features. In some embodiments, the height SH correlates to the fin height H1. In some embodiments, a ratio of the height SH over the fin height H1 is in a range between about 0.1 and about 1.4. In some embodiments, the height SH is in a range between about 6 nm and about 40 nm. A spacer height SH greater than 40 nm may cause electrical short circuit between gate electrode structure and source/drain contact. A spacer height SH less than 6 nm may not be high enough to provide isolation to the gate electrode structure.

In conventional technology, sidewall spacers are pulled back after replacement gate electrode layers are formed. For example, the sidewall spacers are etched back during gate electrode etch back process. By pulling back the sidewall spacers 224 prior to formation of the replacement electrode layers, embodiments of the present disclosure expand upper portions of the gate cavities 234. The expanded upper portions reduce formation of seams or voids in gate structures with short gate length during replacement gate filling, thus providing uniformity and stability in replacement gate etch back. At this stage, the CESL 228 is exposed to the gate cavities 234. As shown in FIGS. 9B, for gate structure with a short gate length, the gate cavity 234s has a T shaped cross section with a smaller width GV1 at a lower portion and a greater width GW1 and GW2 at the upper portion. In some embodiments, because the sacrificial gate electrode 212 has a substantially straight profile, the width GW1 of the gate cavity 234s at the top surface 224t of the sidewall spacers 224 and the width GW2 of the gate cavity 234s at near the cap dielectric layer 232 are substantially the same. In some embodiments, the width GW1 is slightly larger than the width GW2. In some embodiments, the difference between GW1 and GW2 is less than about 2 nm.

In some embodiments, the sacrificial gate dielectric layer 210 is also removed while etching the sidewall spacers 224 to expose the semiconductor fins 204 in the gate cavity 234. In other embodiments, the sacrificial gate dielectric layer 210 may be removed using a separate etching process, such as plasma dry etching and/or wet etching.

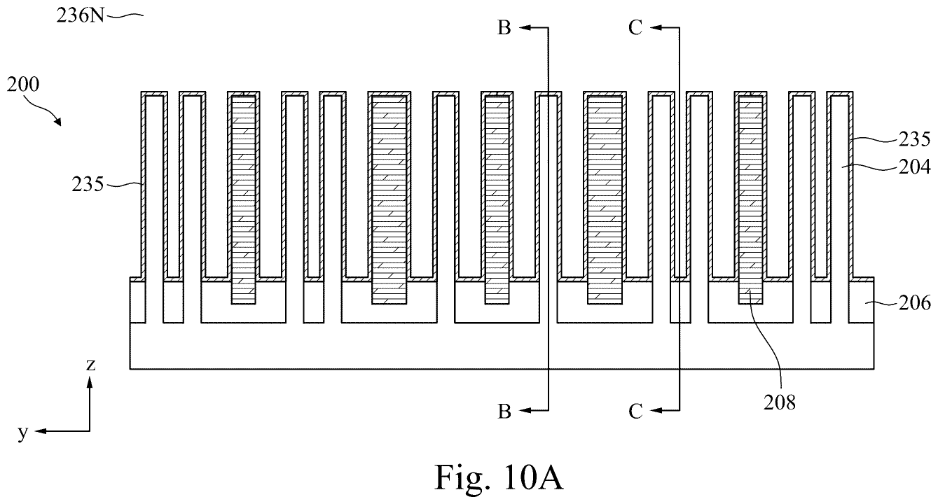

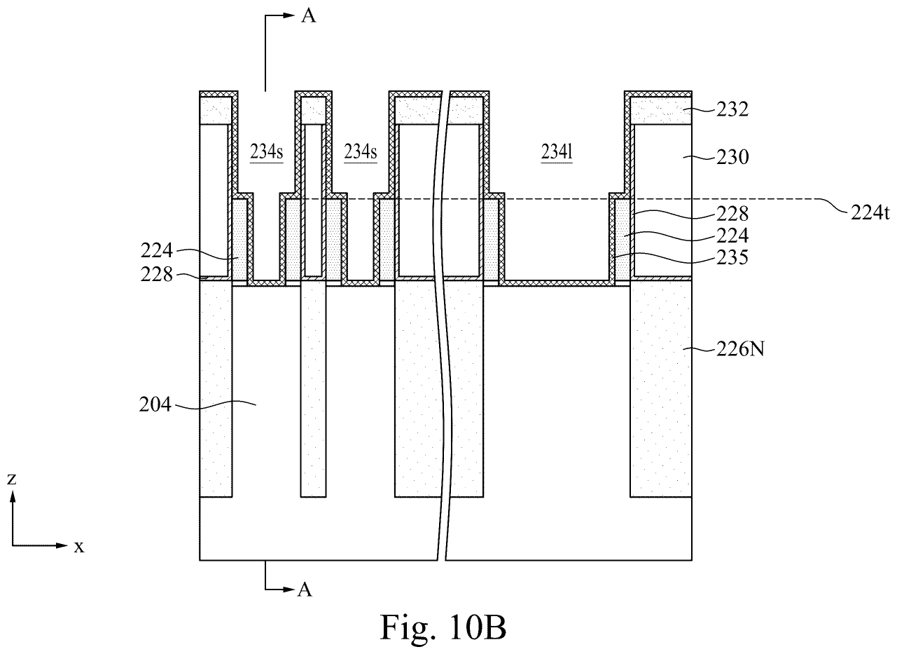

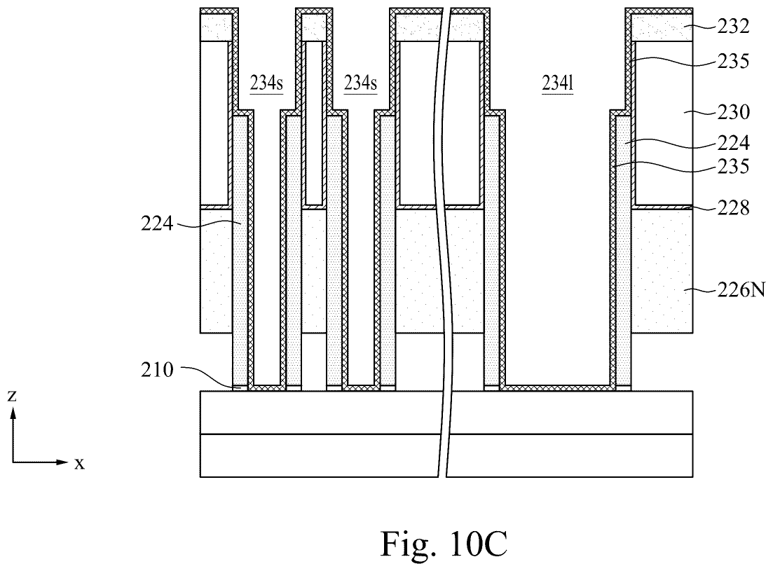

At operation 118, a gate dielectric layer 235 is formed on gate cavities 234, as shown in FIGS. 10A-10C. FIG. 10A is a schematic cross-sectional view of the semiconductor device 200 along the Y direction across line A-A in FIG. 10B. FIGS. 10B and 10C are schematic cross-sectional views of the semiconductor device 200 along lines B-B, C-C in FIG. 10A respectively.

In some embodiments, the gate dielectric layer 235 is first deposited on exposed surfaces of the gate cavities 234. The gate dielectric layer 235 is formed on the exposed surfaces of the semiconductor fins 204, the sidewall spacers 224, the CESL layer 228, and the STI layer 206.

The gate dielectric layer 235 includes a single layer or a stack of insulating material layers. In some embodiments, the gate dielectric layer 235 includes one or more layers of silicon oxide, silicon nitride, silicon oxy-nitride, or high-k dielectric materials such as hafnium oxide (HfO₂), TiO₂, HfZrO, Ta₂O₅, HfSiO₄, ZrO₂, ZrSiO₂, or combinations thereof. In some embodiments, the gate dielectric layer 235 may include high-k dielectric materials such as metal oxides used for high-k dielectrics include oxides of Li, Be, Mg, Ca, Sr, Sc, Y, Zr, Al, La, Ce, Pr, Nd, Sm, Eu, Gd, Tb, Dy, Ho, Er, Tm, Yb, Lu, and/or mixtures thereof. The high-k dielectric layer may be formed by ALD and/or other suitable methods. In some embodiments, the gate dielectric layer 235 may include silicon oxide formed by CVD, ALD, physical vapor deposition (PVD), e-beam evaporation, or other suitable process. In some embodiments, the gate dielectric layer 235 has a thickness in the range of about 1 nm to about 5 nm.

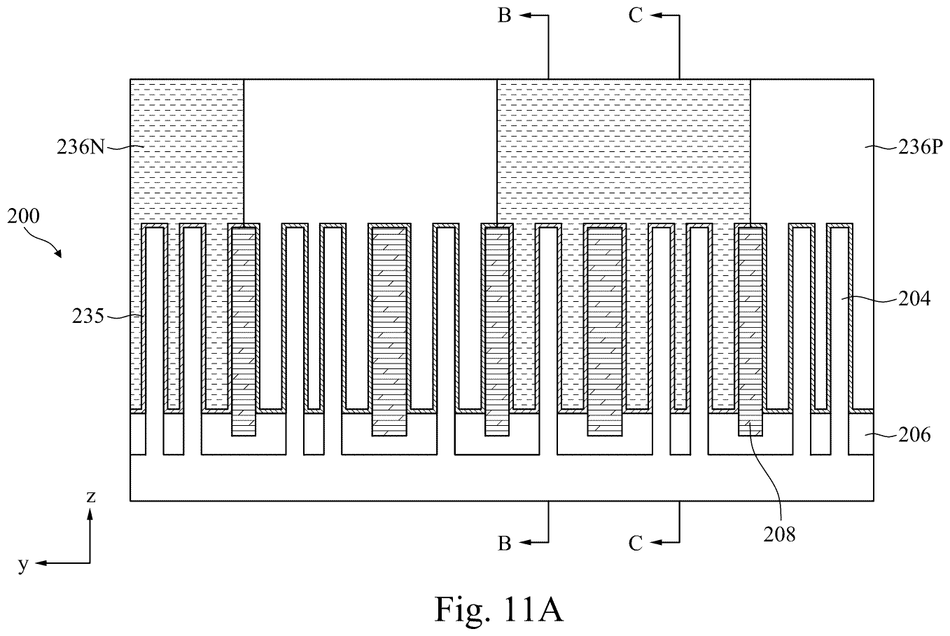

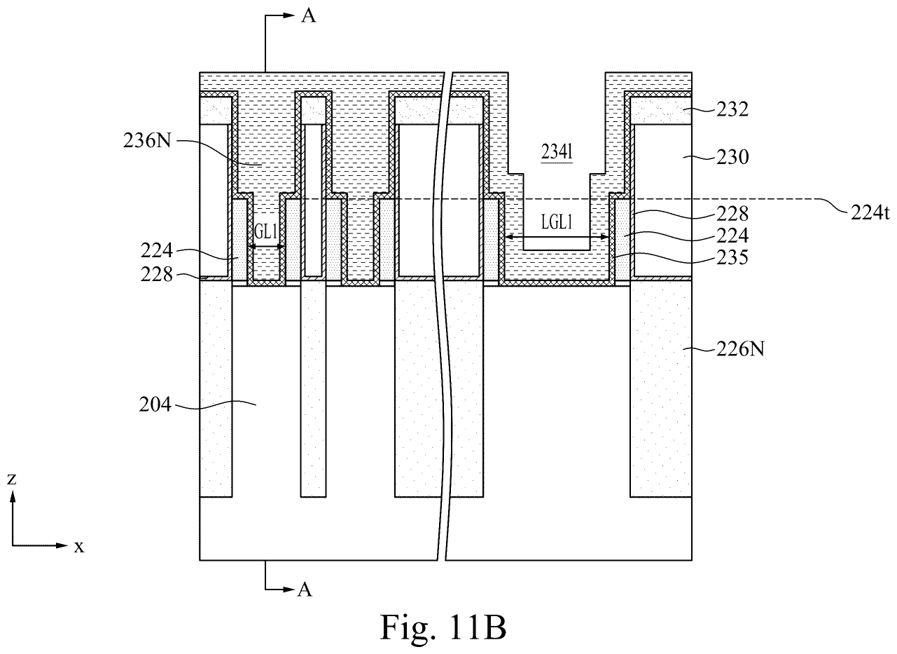

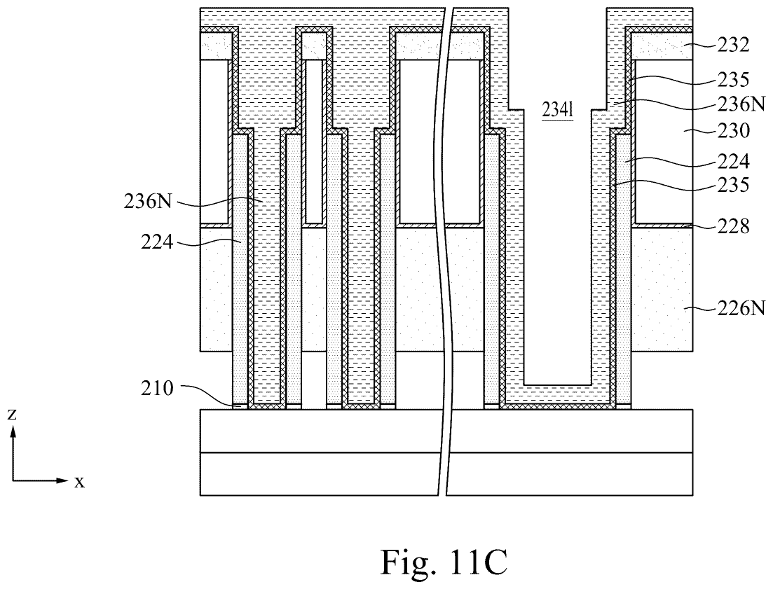

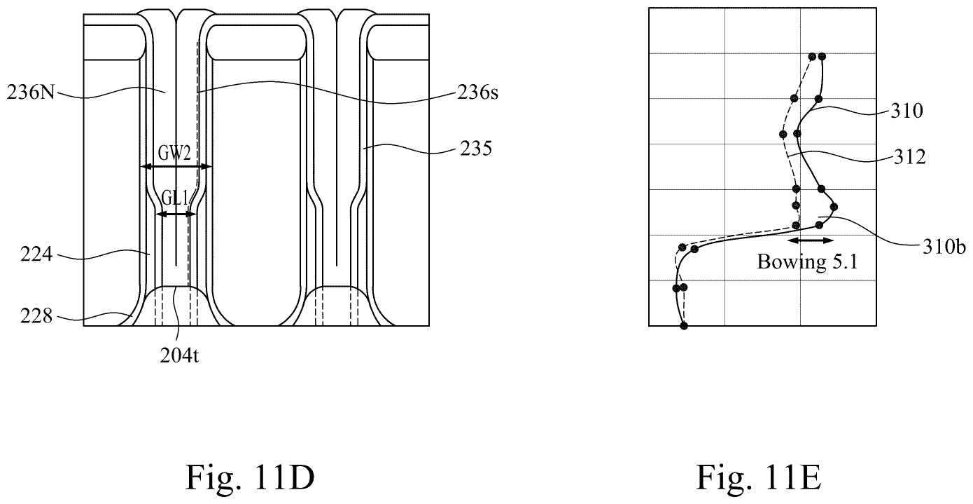

At operation 120, work function metal layers 236N, 236P (collectively 236) is then formed on the gate dielectric layer 235, as shown FIGS. 11A-11C. FIG. 11A is a schematic cross-sectional view of the semiconductor device 200 along the Y direction across line A-A in FIG. 11B. FIGS. 11B and 11C are schematic cross-sectional views of the semiconductor device 200 along lines B-B, C-C in FIG. 11A respectively.

The function metal layer 236 is configured to set a threshold voltage for the subsequently formed transistor. The work function metal layer 236 may include a single metallic layer or a stack of metallic layers. The stack of metallic layers may include metals having work functions similar to or different from each other. In some embodiments, the work function metal layer 236 includes any suitable material, such as aluminum (Al), copper (Cu), tungsten (W), titanium (Ti), tantalum (Ta), titanium nitride (TiN), tantalum nitride (TaN), nickel silicide (NiSi), cobalt silicide (CoSi), silver (Ag), TaC, TaSiN, TaCN, TiAl, TiAlN, WN, metal alloys, and/or combinations thereof. The work function metal layer 236N for the n-type device and the work function metal layer 236P for the p-type device may include different materials or different combinations of material layers. Exemplary materials for the work function metal layer 236P in a p-type device may include TiN, TaN, Ru, Mo, Al, WN, ZrSi2, MoSi2, TaSi2, NiSi2, WN, other suitable p-type work function metals, or combinations thereof. Exemplary materials for the work function metal layer 236N in a n-type device may include TiAlC, Ti, Ag, TaAl, TaAlC, TiAlN, TaC, TaCN, TaSiN, Mn, Zr, other suitable n-type work function materials, or combinations thereof.

The work function metal layer 236 may be formed using a suitable process such as ALD, CVD, PVD, plating, or combinations thereof. In some embodiments, the work function metal layers 236N, 236P may be formed in separated processes using suitable masks to cover unprocessed areas of the substrate. In some embodiments, the work function metal layer 236 has a thickness in the range of about 2 nm to about 15 nm.

In the example of FIGS. 11B and 11C, after deposition the work function metal layer 236, the gate cavities 234s with the short gate length GL1, for example with the gate length GL1 in a range between about 8 nm and 15 nm, is filled by the gate dielectric layer 235 and the work function metal layer 236. Because of the gate cavities 234s has substantially the T-shape prior to deposition of the work function metal layer 236 and the gate cavity 234s has substantially straight sidewall profiles, the work function metal layer 236 is seam free and void free.

FIG. 11D includes outlines traced from a transmission electron microscope (TEM) image of a semiconductor device similar to the semiconductor device 200 after operation deposition of the work function metal layer 236. As demonstrated in FIG. 11D, the work function metal layer 236 is void free.

FIG. 11E includes profiles of sidewalls of the work function metal layer. Curve 310 is a sidewall profile of a work function metal layer in a gate cavity according to current technology. Curve 310 includes a bowled portion 310b. Curve 312 is a sidewall profile 236s (FIG. 11D) of the work function metal layer 236 in a gate cavity according to embodiments of the present disclosure. The curve 312 includes substantially straight sections.

Referring back to FIGS. 10B and 10C, after deposition of the work function metal layer 236, the gate cavities 234l with long gate length still have a substantially T-shaped cross section with a wider upper portion. Additional conductive and dielectric filling may be formed to fill the gate cavities 234l.

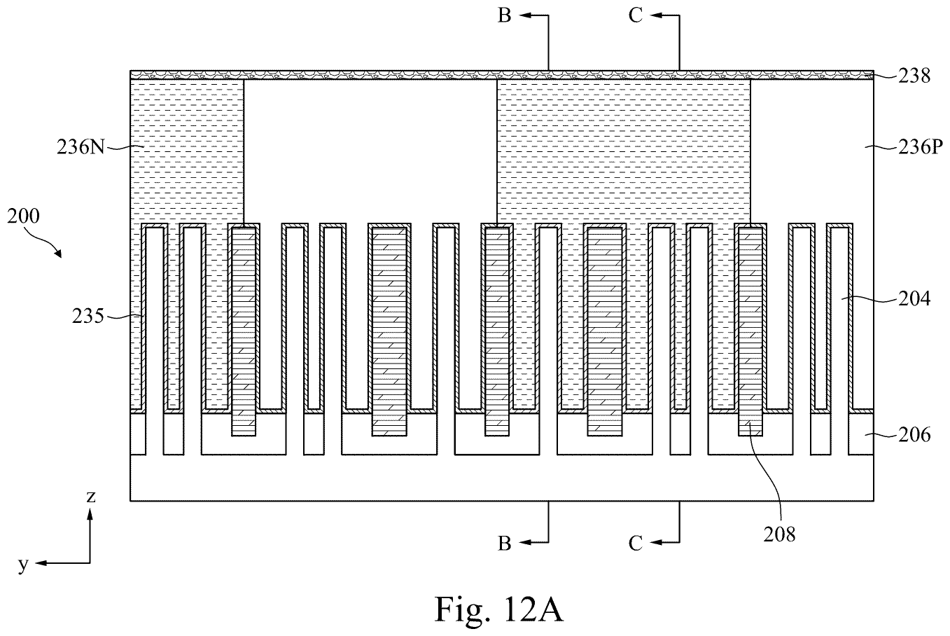

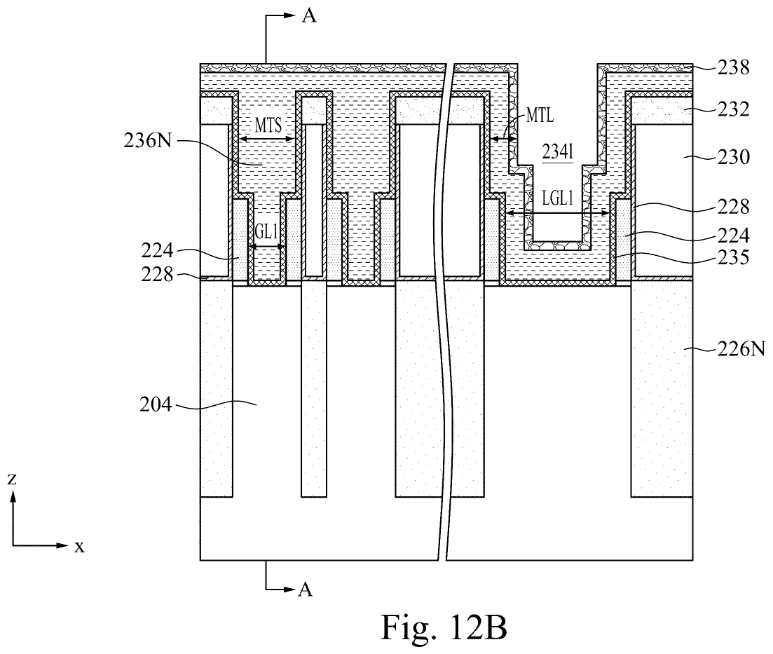

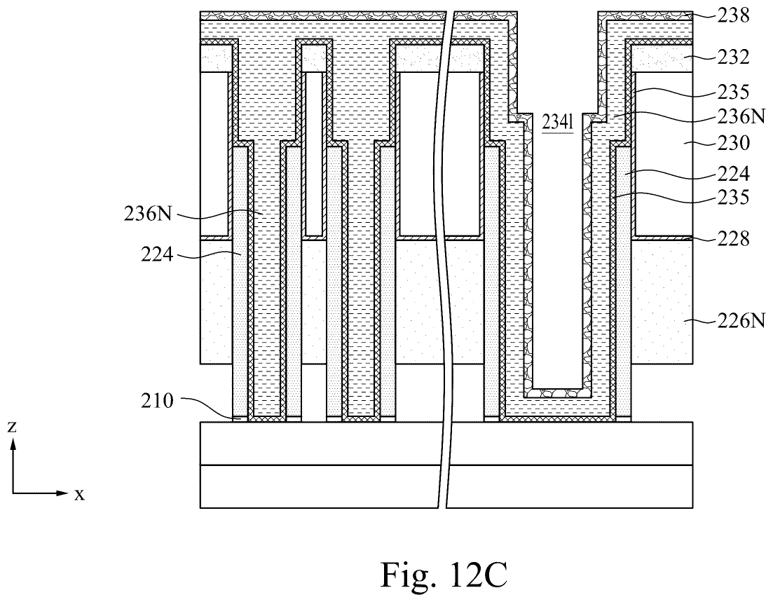

At operation 122, a conductive filling layer 238 is deposited on the work function metal layer 236, as shown in FIGS. 12A-12C. FIG. 12A is a schematic cross-sectional view of the semiconductor device 200 along the Y direction across line A-A in FIG. 12B. FIGS. 12B and 12C are schematic cross-sectional views of the semiconductor device 200 along lines B-B, C-C in FIG. 12A respectively.

The conductive filling layer 238 may include one or more metals, such as W, Al, Co, or other suitable metals, or alloy thereof. In some embodiments, the conductive filling layer 238 may include a fluorine-free tungsten (FFW) layer to prevent fluorine from diffusing into underlying layers, such as the work function metal layer 236 and the gate dielectric layer 235. The FFW layer may be formed by a chemical vapor deposition process, using a tungsten comprising precursor, such as W(CO)₆. During deposition, the W(CO)₆ precursor decomposes into a layer of tungsten and carbon dioxide. In some embodiments, the deposition may be performed at a temperature of between about 200° C. and about 450° C., and at a pressure of less than about 2 Torr. In some embodiments, the fluorine free tungsten layer may have a thickness between about 1 nm and about 5 nm.

In some embodiments, the conductive filling layer 238 includes a FFW layer as a tungsten nucleation layer, and a second metal layer on top of the FFW layer. For example, a second layer comprising a metallic material such as W, Al, Cu, AlCu, W, Ti, TiAlN, TaC, TaCN, TaSiN, Mn, Zr, TiN, Ta, TaN, Co, Ni, combinations of thereof.

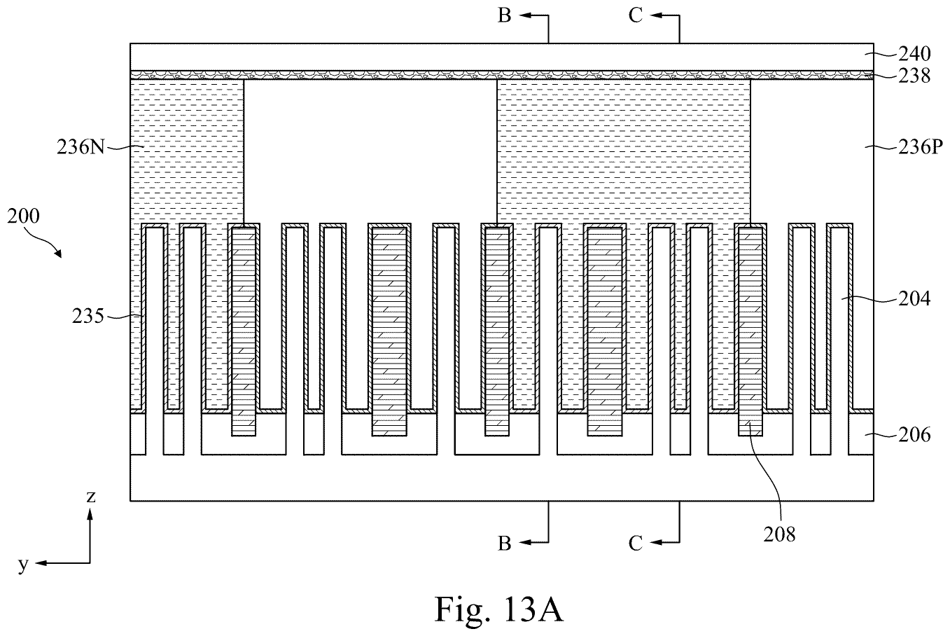

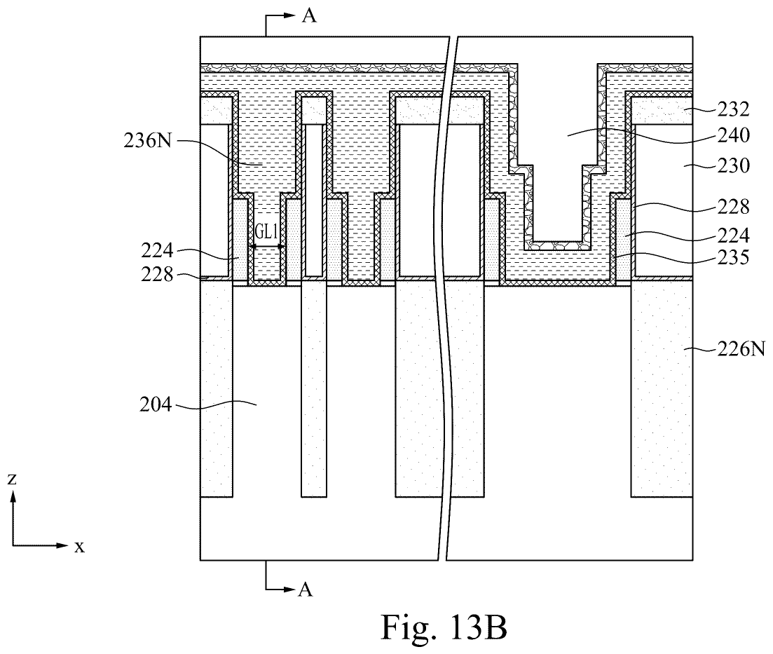

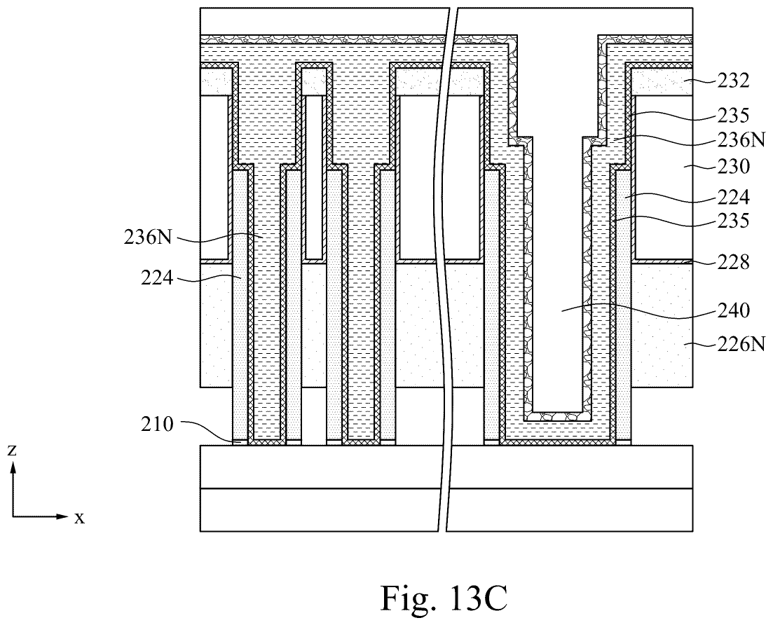

In FIGS. 13B and 13C, the gate cavity 234l still has opening above and below the top surface 224t of the sidewall spacer 224 after formation of the conductive filling layer 238. In some embodiments, the thickness of the conductive filling layer 238 is selected so that the combined thickness MTL (FIG. 13B) on the sidewall of the gate cavity 234L is close to the thickness MTS in the gate cavity 234s. For example, a ratio of MTL over MTS is in a range between about 0.8 and 1.2. As discussed later, the similarity in thickness facilitates uniform etching rates across gates with different gate length during etch back process.

Depending on the gate length, a lower portion of the gate cavity 234l may be filled while the upper portion remains open, or the entire gate cavity 234l may be filled. In such cases, the semiconductor device 200 may have different gate structures.

At operation 124, a dielectric filling layer 240 is filled in remaining openings in the gate cavities 234, as shown in FIGS. 13A-13C. FIG. 13A is a schematic cross-sectional view of the semiconductor device 200 along the Y direction across line A-A in FIG. 13B. FIGS. 13B and 13C are schematic cross-sectional views of the semiconductor device 200 along lines B-B, C-C in FIG. 13A respectively.

The dielectric filling layer 240 may be formed by a suitable deposition process, for example by ALD, or plasma enhanced chemical vapor deposition (PECVD), or a combination of ALD and PECVD (e.g., a lower portion being formed by ALD, and an upper portion being formed by PECVD). In some embodiments, the dielectric filling layer 240 may include silicon nitride. In other embodiments, the dielectric filling layer 240 may include silicon oxide. The dielectric filling layer 240 divides gate cavities with a long gate length into two smaller portions of conductive areas which are similar in size to conductive areas in gate cavities with short gate length.

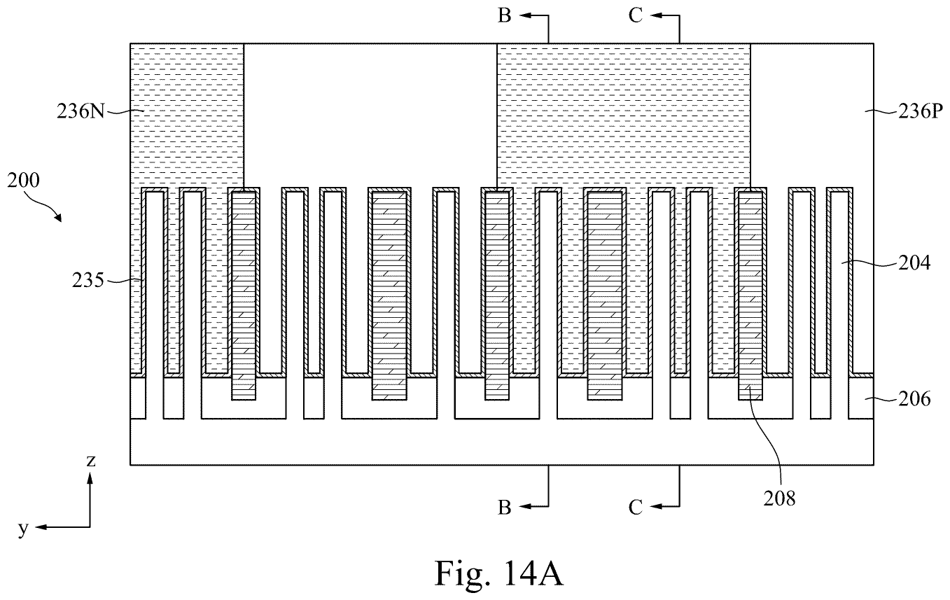

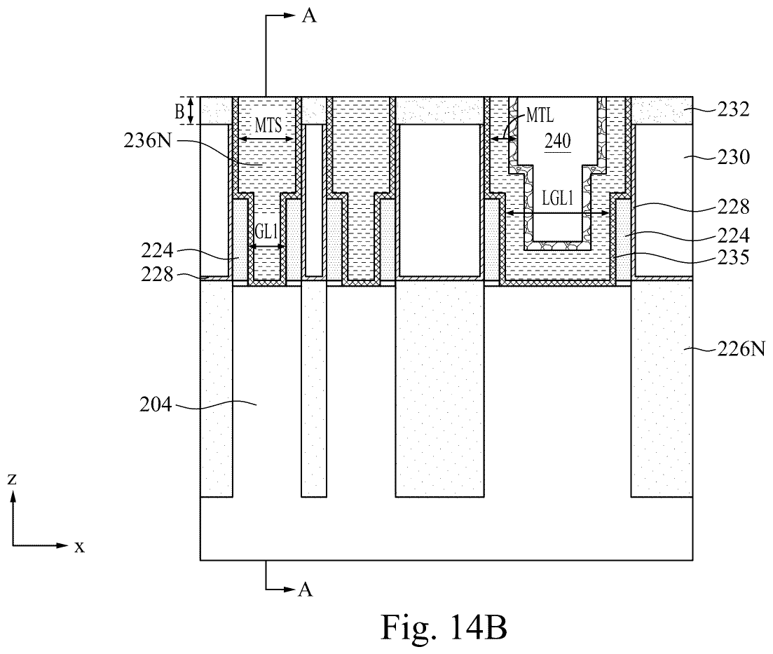

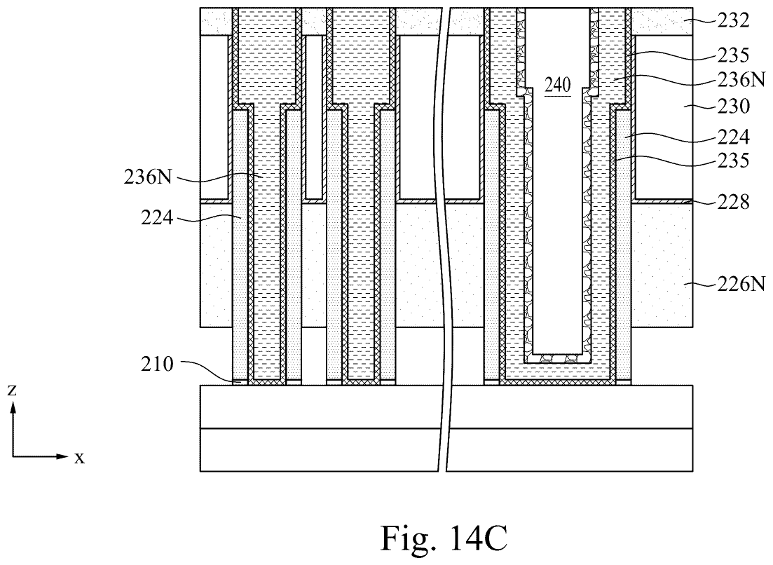

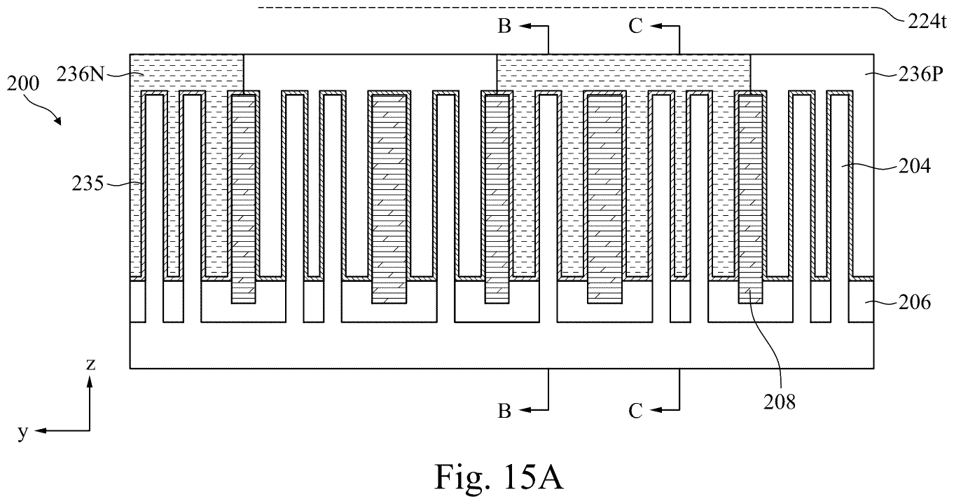

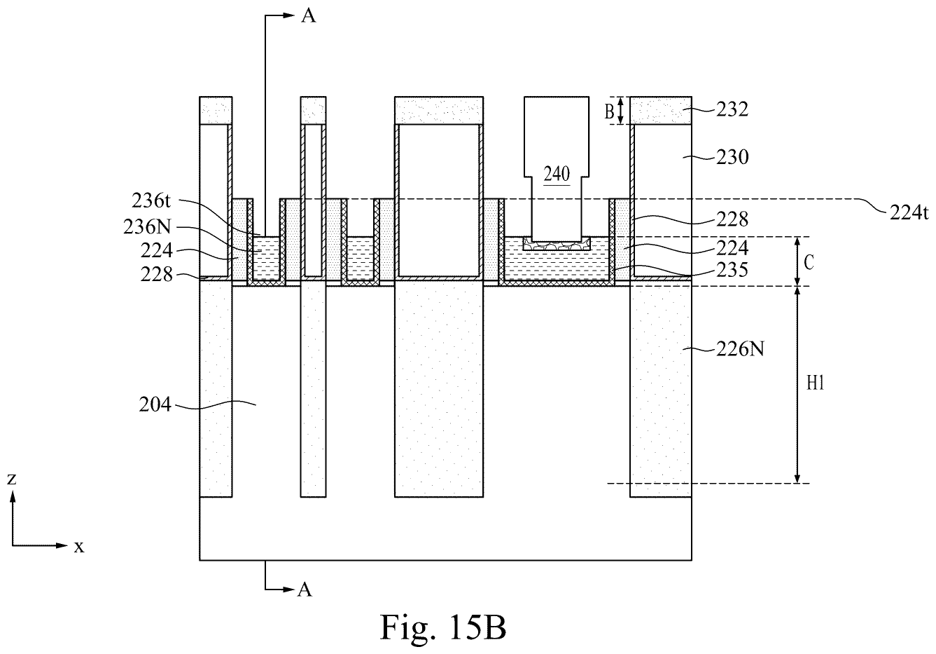

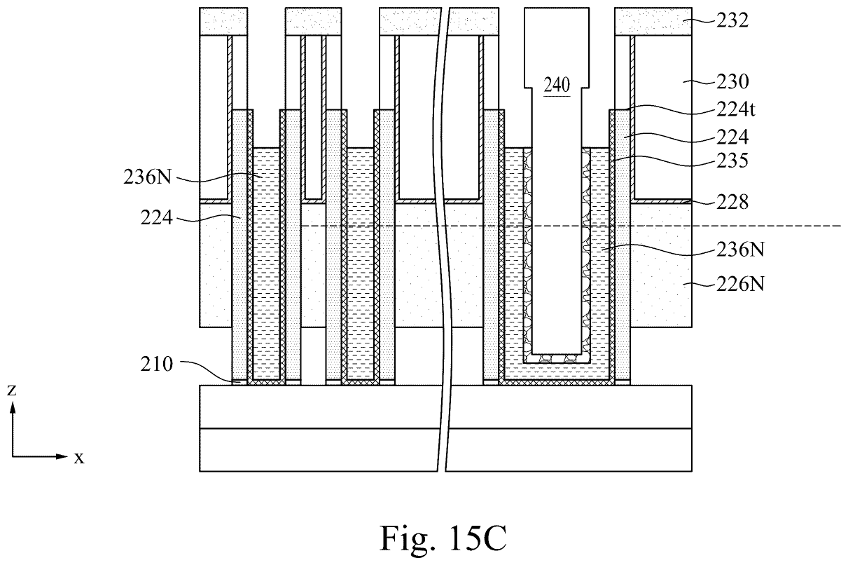

At operation 126, an etch back process is performed to remove upper portions of the conductive filling layer 238 and the work function metal layer 236, as shown in FIGS. 14A-14C and 15A-15C. FIG. 14A is a schematic cross-sectional view of the semiconductor device 200 along the Y direction across line A-A in FIG. 14B. FIGS. 14B and 14C are schematic cross-sectional views of the semiconductor device 200 along lines B-B, C-C in FIG. 14A respectively. FIG. 15A is a schematic cross-sectional view of the semiconductor device 200 along the Y direction across line A-A in FIG. 15B. FIGS. 15B and 15C are schematic cross-sectional views of the semiconductor device 200 along lines B-B, C-C in FIG. 15A respectively.

Prior to etching back, a planarization process is performed to remove excessive depositions of the conductive filling layer 238, the work function metal layer 236 and the gate dielectric layer 235, as shown in FIGS. 14A-14C. In some embodiments, a thickness B of the cap dielectric layer 232 may be in a range from 5 nm and 30 nm after the planarization process. A thickness B less than 5 nm may cause loss of the ILD layer 230 during subsequent etching. A thickness B greater than 30 nm may increase the aspect ratio of the recess process without additional benefit.

One or more etching processes may be performed to selective etching back conductive layers, i.e. the work function metal layer 236 and the conductive filling layer 238 are etched back to a level below the top surface 224t of the sidewall spacer 224. In some embodiments, the etch process may use one or more of the following materials as etchants: BCl₃, Cl₂, CF₄, NF₃, HBr/NF₃, Cl₂/O₂/N₂/NF₃, CHF₃/H₂/Ar, or combinations thereof.

After the etch back process, a top surface 236t of the work function metal layer 236 is below the top surface 224t of the sidewall spacers 224, and at a distance C from the top surface 204t of the semiconductor fins 204. In some embodiments, the distance C is in a range between about 6 nm and 14 nm. A distance C below 6 nm may cause electrical break through to the channel region, i.e. the semiconductor fin 204. A distance greater than 14 nm may cause gate electrodes to spill over the sidewall spacers 224 resulting in short circuit with the subsequently formed source/drain contacts.

The distance C across gate structures with various gate lengths are substantially uniform. This is because there are no voids or seams formed in the work function metal layer 236 and the conductive filling layer 238 being etched and the dimensions of the material being processed, i.e. MTS and MTL are comparable.

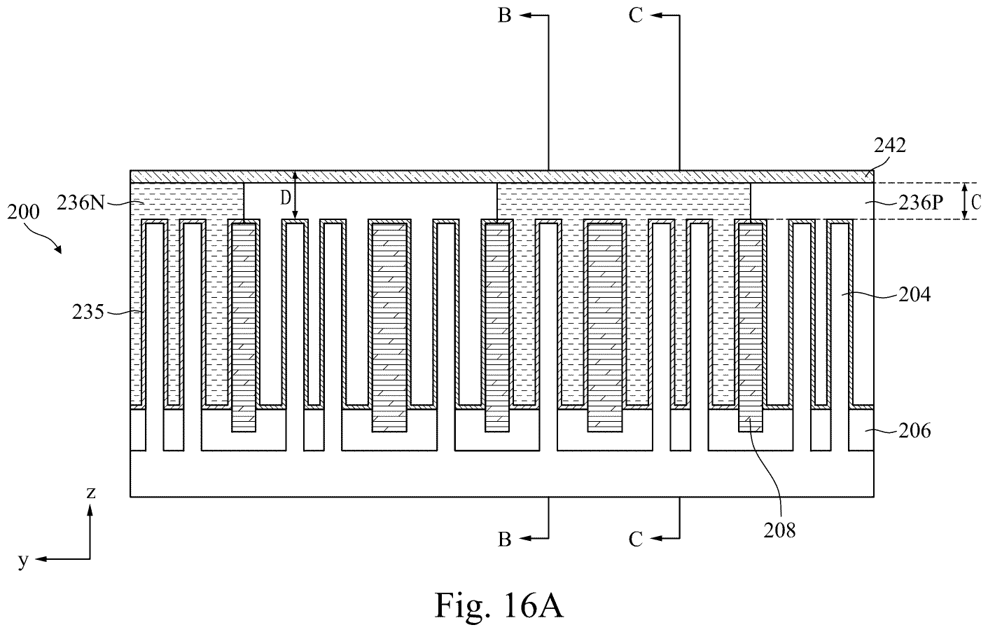

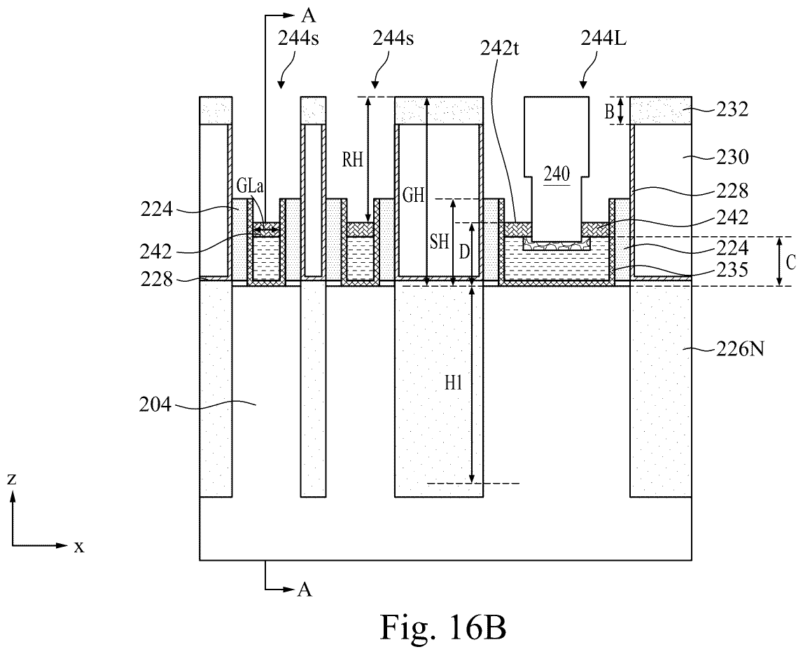

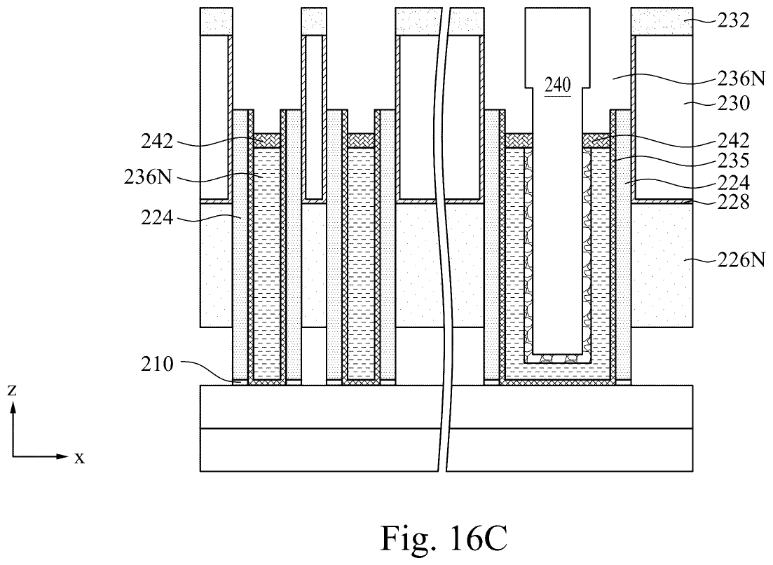

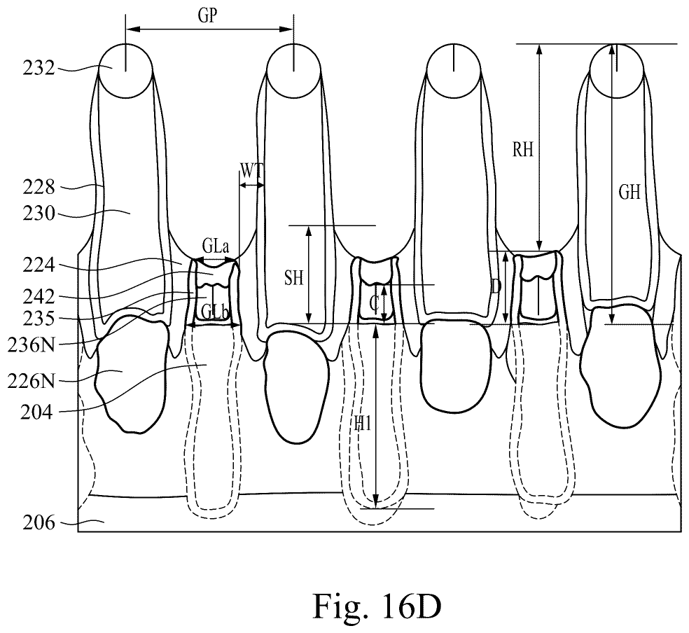

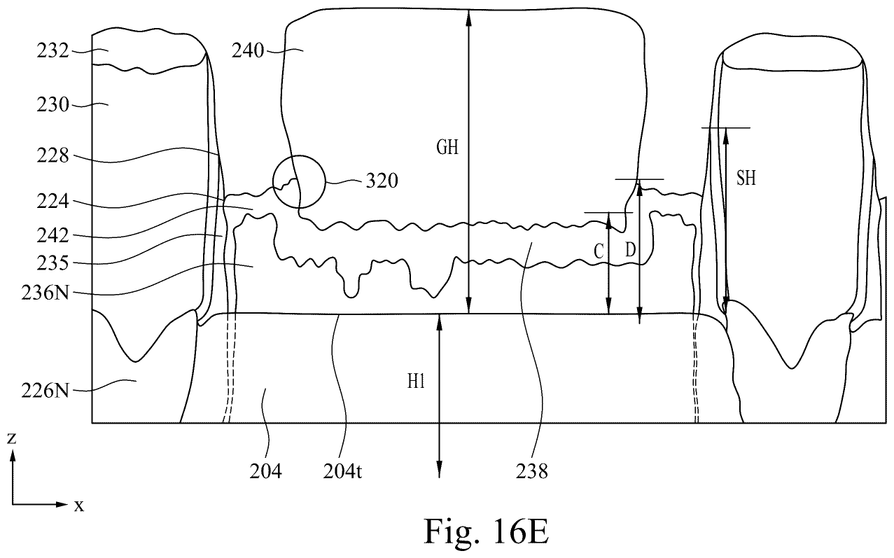

At operation 128, a top conductive layer 242 is selectively formed over the work function metal layer 236 and the conductive filling layer 238 if exposed, as shown in FIGS. 16A-16C. FIG. 16A is a schematic cross-sectional view of the semiconductor device 200 along the Y direction across line A-A in FIG. 16B. FIGS. 16B and 16C are schematic cross-sectional views of the semiconductor device 200 along lines B-B, C-C in FIG. 16A respectively.

In some embodiments, a wet clean and a pre-soaking process may be performed prior to selective formation of the top conductive layer 242. A pre-soaking process may remove oxygen from the conductive filling layer 238 and prevent void formation in the subsequent deposition. In some embodiments, the pre-soaking process is performed using any suitable precursor that reacts with oxygen, such as WF₆, B₂H₆, and the like.

In some embodiments, the top conductive layer 242 may be a fluorine free tungsten layer selectively formed on the work function metal layer 236 and the conductive filling layer 238. The top conductive layer 242 may be formed by a chemical vapor deposition process, using a tungsten comprising precursor, such as W(CO)₆. During deposition, the W(CO)₆ precursor decomposes into a layer of tungsten and carbon dioxide. In some embodiments, the deposition may be performed at a temperature of between about 200° C. and about 450° C. and at a pressure of less than about 2 Torr.

After formation of the top conductive layer 242, replacement gate structures 244L, 244S (collectively 244) are complete. The replacement gate structure 244s has a shorter gate length than the replacement gate structure 244l.

As shown in FIG. 16B, after the planarization at operation 116, a gate height GH may be measured from the top surface of the semiconductor device 200 and the top surface 204t of the semiconductor fin 204. After the deposition of the top conductive layer 242, a top surface 242t of the top conductive layer 242 is at a distance RH, i.e. metal gate recess, from the top surface of the semiconductor device 200. In some embodiments, the distance RH is in a range between about 40 nm and 75 nm depending on circuit design.

The top surface 242t of the top conductive layer 242 is a distance D from the top surface 204t of the semiconductor fin 204. The distance D is less than the spacer height SH. In some embodiments, the distance D is in a range between about 6 nm and 40 nm. If the distance D is greater than 40 nm, the gate electrode may short circuit with neighboring source/drain contacts. If the distance D is less than 6 nm, the gate structure may “punch” through the semiconductor fin 204 and lower wafer acceptance testing (WAT) performance. In some embodiments, to improve WAT performance, the distance D is selected according to the fin height H1. For example, a ratio of the distance D over the fin height H1 is in. arrange between about 0.1 and about 0.7. In some embodiments, to increase etching winding for source/drain contact, the distance D may be selected according to the gate height GH. For example, a ratio of the gate height GH over the distance D may be in a range between about 2 and about 8. In some embodiments, a ratio of the sidewall height SH over the distance D is in a range between about 0.5 to above 2.0.

At this stage, a combined thickness WT of the sidewall spacers 224 and the CESL 228 is in a range between about 5 nm and 13 nm to avoid loss of the ILD layer 230 or lateral etching.

The semiconductor device 200 includes gate structures of different width and pitches. The replacement gate structure 244s has a shorter gate length. In some embodiments, the replacement gate structures 244s may have a gate pitch GP (gate to gate distance) in a range between about 20 nm and 30 nm. The replacement gate structure 244s has a gate length GLa near the top surface 242t of the top conductive layer 242 and a gate length GLb near the top surface 204t of the semiconductor fin 204. In some embodiments, the gate length GLa may be in a range between about 10 nm and 15 nm. In some embodiments, the gate length GLb may be in a range between about 13 nm and 20 nm. In some embodiments, the gate length GLb is greater than the gate length GLa. The smaller gate length GLa at top helps slowing down etching rate during gate etch back process at operation 116, thus, preventing “punch through”. In some embodiments, a ratio of the gate length GLa over the gate length GLb may be in a range between about 0.5 and about 0.8. A ratio larger than 0.8 may not reduce etching rate during etching back. A ratio less than 0.5 may cause voids to form during deposition.

In some embodiments, the replacement gate structures 244l have a long gate length, for example with a gate length greater than 20 nm. In the replacement gate structure 244l, both the work function metal layer 236 and the conductive filling layer 238 have a U-shape cross section. The conductive filling layer 238 is disposed in the U-shape of the work function metal layer 236. A portion of the dielectric filling layer 240 is disposed in the U-shape of the conductive filling layer 238. The top conductive layer 242 is formed over the work function metal layer 236 and the conductive filling layer 238, and around a lower portion of the dielectric filling layer 240.

In some embodiments, the distance C, which is measured from the top surface 238t of the conductive filling layer 238 and the top surface 204t of the semiconductor fin 204, may be in a range between about 15 nm and 35 nm. If the distance C is less than 15 nm, the dielectric filling layer 240 may peel from the conductive filling layer 238. In the gate structures 244l, the ratio of the gate height GH over the distance D may be in a range between about 3 and about 5 to ensure a desirable etching window for the source/drain contact. In some embodiments, horn shapes may occur at corners of the top conductive layer 242. In some embodiments, the distance D is less than about 40 nm to prevent gate electrode short circuit.

FIG. 16D includes outlines traced from a transmission electron microscope (TEM) image of gate structures with a short gate length in a semiconductor device similar to the semiconductor device 200 after operation 128. FIG. 16D includes outlines traced from a transmission electron microscope (TEM) image of a gate structure with a long gate length in a semiconductor device similar to the semiconductor device 200 after operation 128. The top conductive layer 242 has a horn shape formed in area 320.

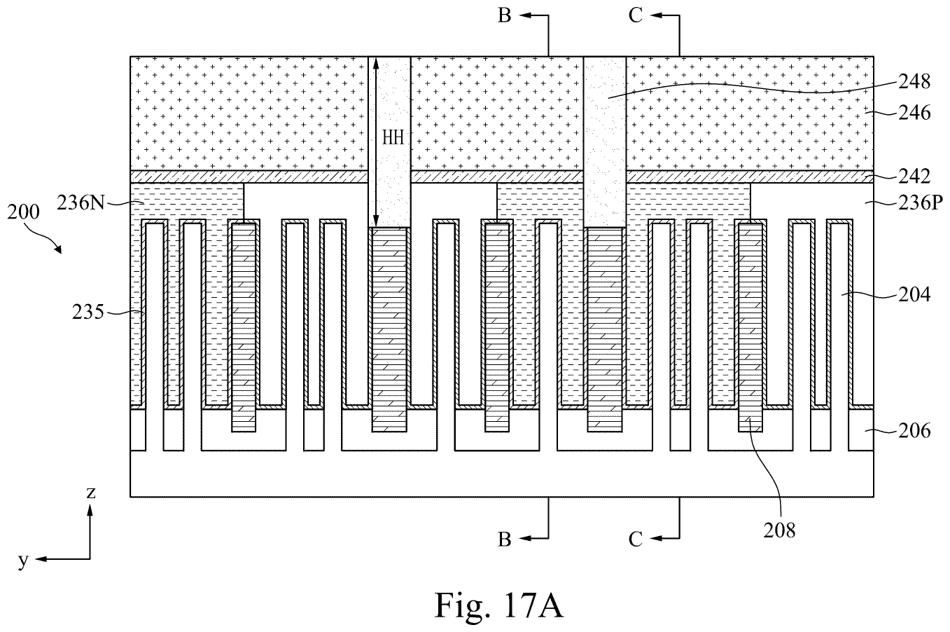

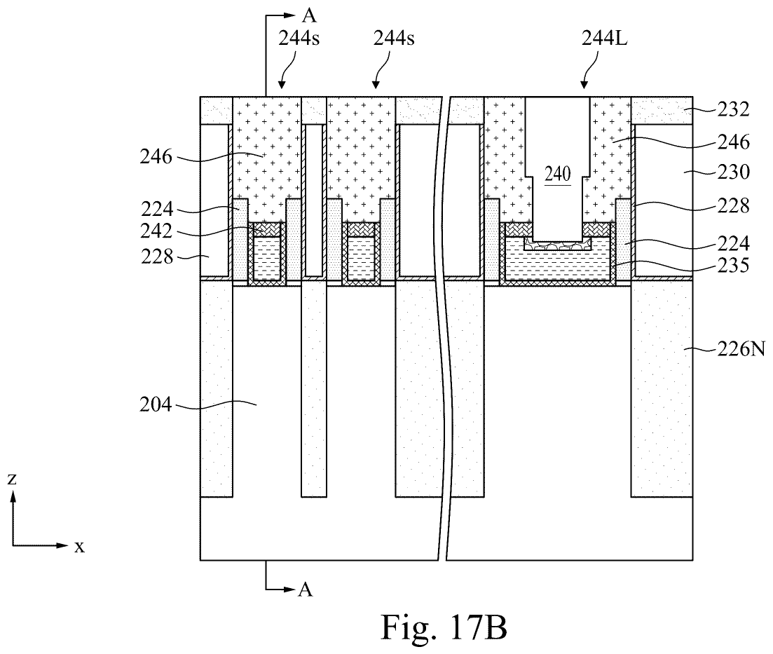

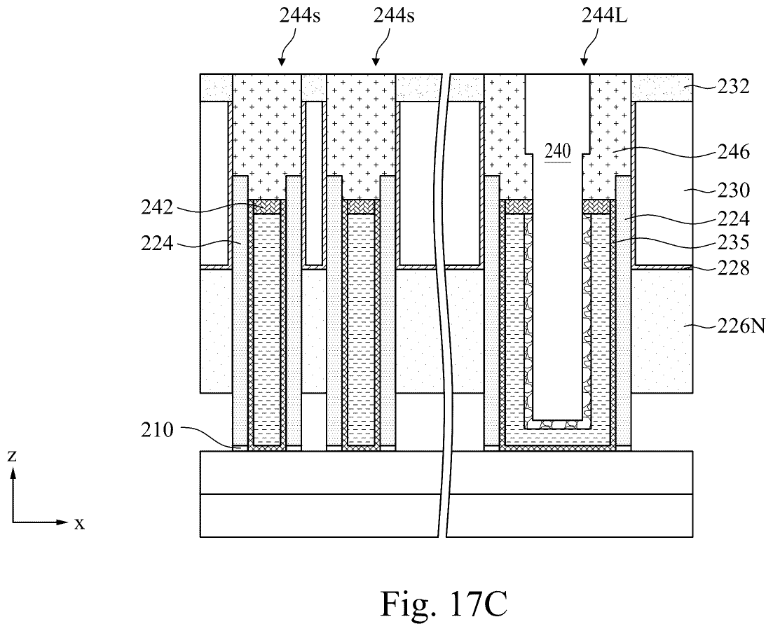

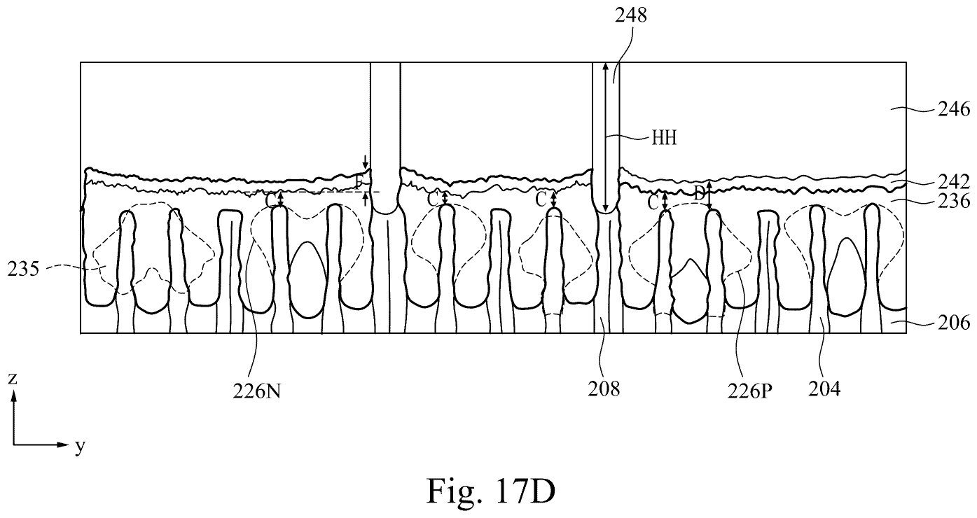

At operation 130, a self-aligned contact (SAC) layer 246 is deposited, and a cut gate process is subsequently performed, as shown in FIGS. 17A-17C. FIG. 17A is a schematic cross-sectional view of the semiconductor device 200 along the Y direction across line A-A in FIG. 17B. FIGS. 17B and 17C are schematic cross-sectional views of the semiconductor device 200 along lines B-B, C-C in FIG. 17A respectively.

The SAC layer 246 may be formed filling the gate cavities above the top conductive layer 242 with a dielectric material, followed by a CMP process to remove excessive materials. The SAC layer 246 may be a dielectric material having an etch selectively relative to the cap dielectric layer 232. A cut-metal-gate process is then performed to form openings through the SAC layer 246 and the replacement gate structures 244. In some embodiments, the openings are aligned with the dielectric fins 208. In other embodiments, the openings may reach the STI layer 206. The openings are then filled with one or more dielectric material, such as high-k dielectric material, to form isolation features 248. As shown in FIG. 17A, the isolation features 258 and the dielectric fins 208 divide the replacement gate structure 244 into multiple electrically isolated sections. In some embodiments, the isolation feature 258 has a height HH. In some embodiments, a ratio of height HH over the distance D may be in a range between about 4 and 8.

FIG. 17D includes outlines traced from a transmission electron microscope (TEM) image of a gate structure across a plurality of semiconductor fins and dielectric fins after operation 130. As shown in FIG. 17D, the distance C, i.e. the distance between the top surface 204t of the semiconductor fins 204 and the top surface 236t of the work function metal layer 236, is substantially uniform across different semiconductor fins, including double fin for p-type device, double fin for n-type device, single fin for p-type device, and single fin for n-type device.

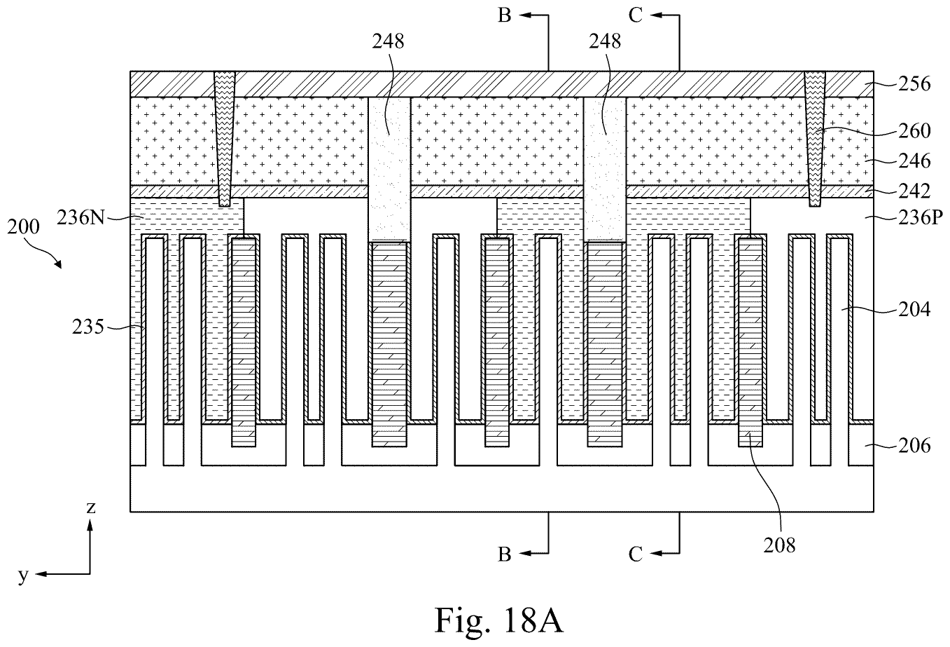

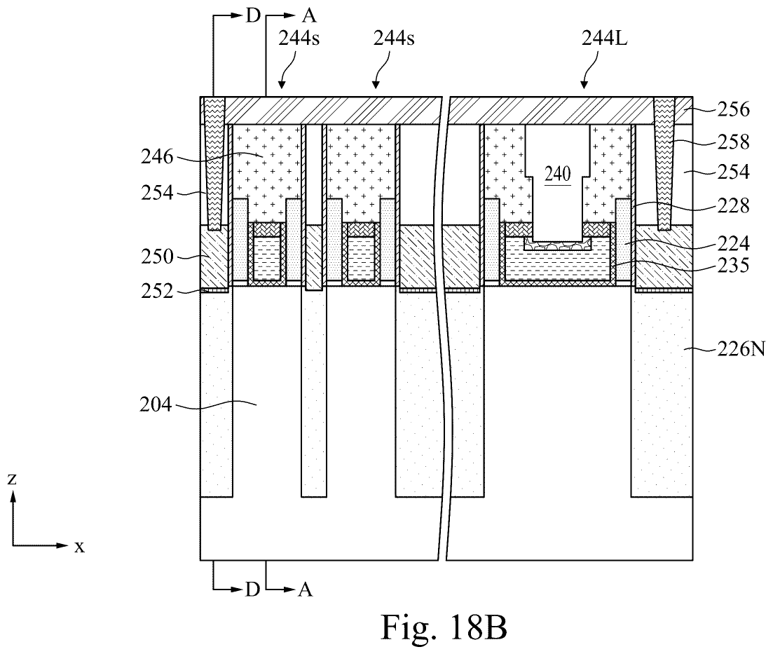

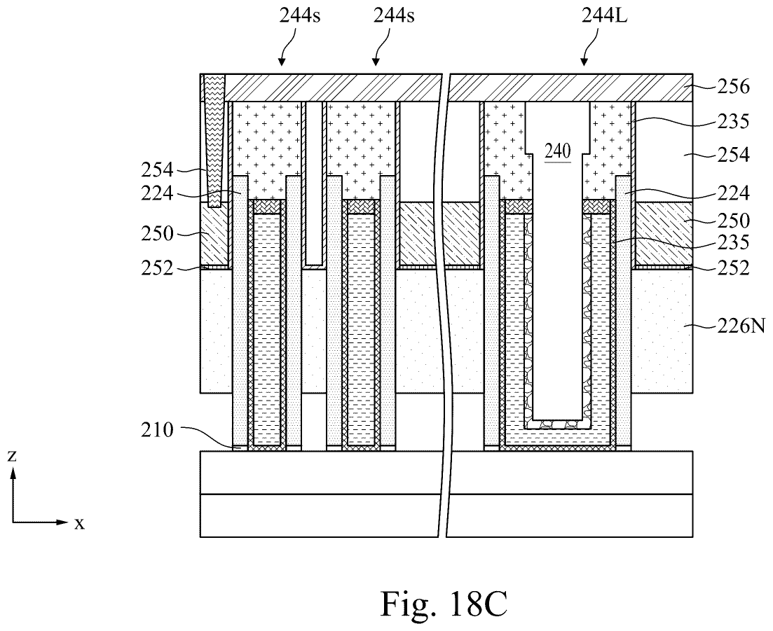

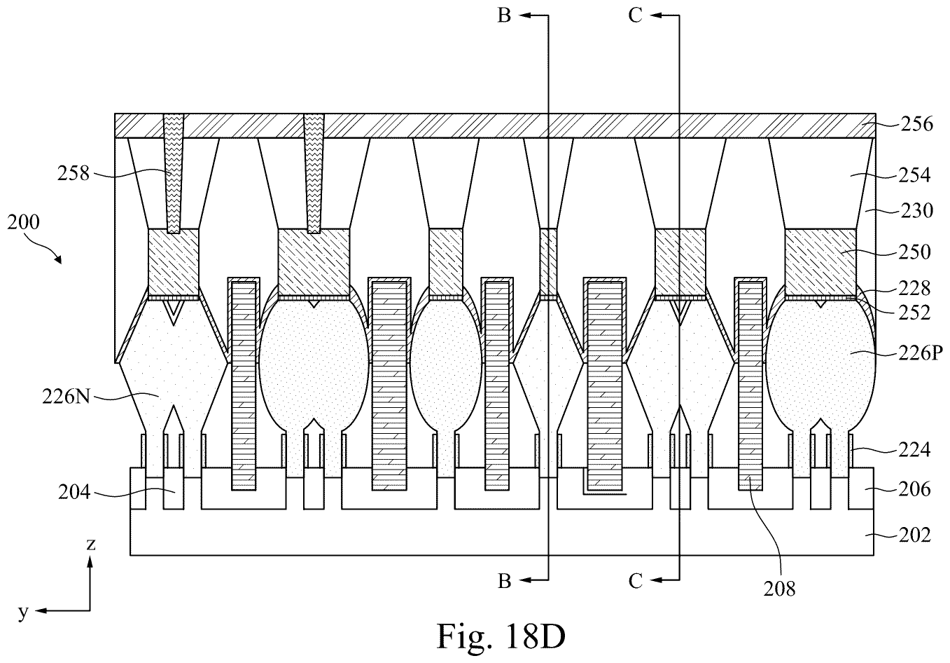

At operation 132, contact features are formed to connect the gate structures 244 and the source/drain regions 226P, 226N, as shown in FIGS. 18A-18D. FIG. 18A is a schematic cross-sectional view of the semiconductor device 200 along the Y direction across line A-A in FIG. 18B. FIGS. 18B and 18C are schematic cross-sectional views of the semiconductor device 200 along lines B-B, C-C in FIG. 18A respectively. FIG. 18D is a schematic cross-sectional view of the semiconductor device 200 along the Y direction across line D-D in FIG. 18B.

A planarization process is performed to remove the cap dielectric layer 232 and expose the ILD layer 230. Contact holes are formed in the ILD layer 230 to expose the source/drain regions 226. Source/drain contacts 250 are then formed in the contact holes. In some embodiments, a silicide layer 252 may be formed between the source/drain contacts 250 and the corresponding source/drain region 236. In some embodiments, a dielectric layer 254 is formed over the source/drain contacts 250. An interlayer dielectric layer 256 may be formed over the semiconductor device 200. Source/drain contact vias 258 and gate contact vias 260 may be formed through the dielectric layer 254 and the SAC layer 246 to electrically connect the source/drain regions 226 and the gate structures 244 to an interconnect structure.

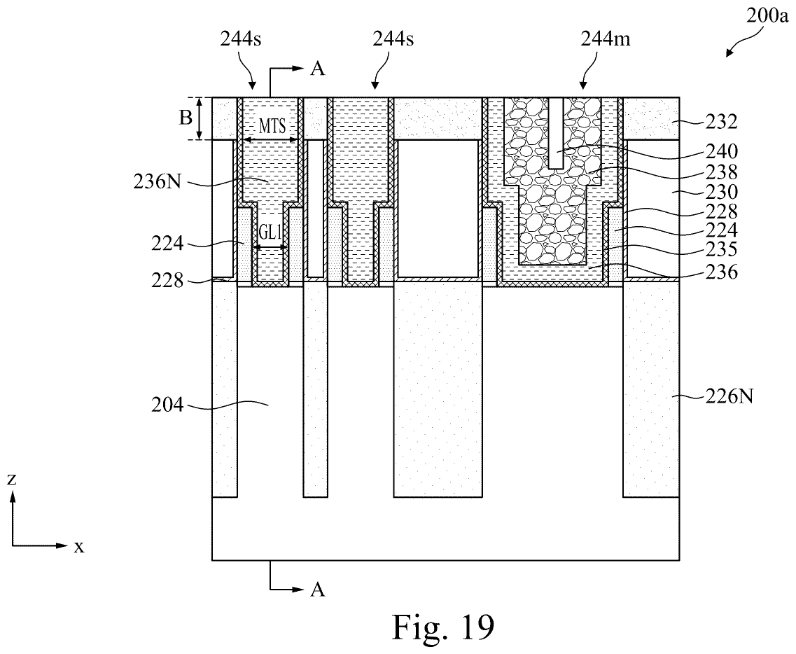

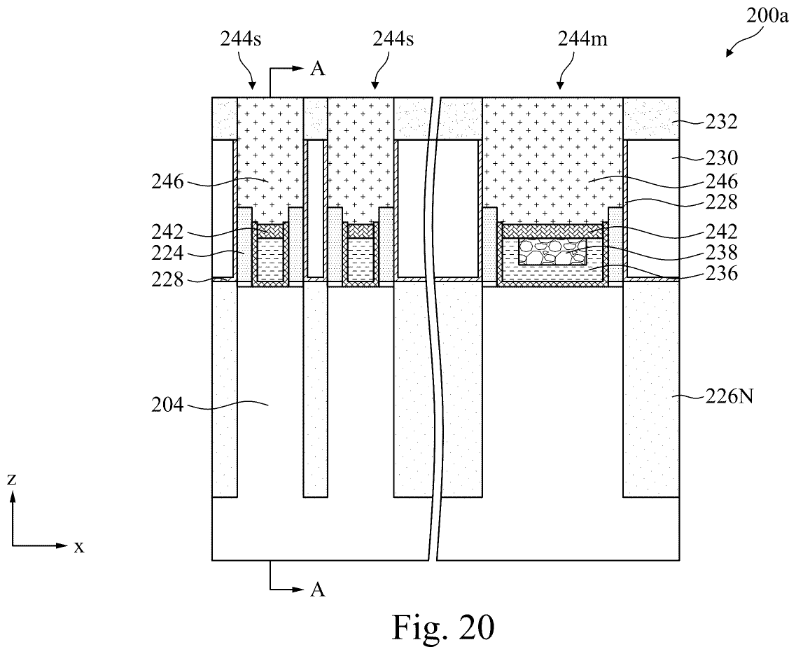

FIGS. 19-20 are schematic cross-sectional views of a semiconductor device 200a according to another embodiment of the present disclosure. The semiconductor device 200a is similar to the semiconductor device 200, except that the semiconductor device 200a includes a replacement gate structure 244m. The replacement gate structure 244m has a gate length longer than the replacement gate structure 244s and shorter than the replacement gate structure 244l.

FIG. 19 is a cross sectional view of the semiconductor device 200a after operation 114. The conductive filling layer 238 fills the lower portion of the gate cavity of the gate structure 244m. The dielectric filling material 240 only forms in the upper portion of the gate cavity.

FIG. 20 is a cross sectional view of the semiconductor device 200a after operation 130. The work function metal layer 236 has a U-shape cross section. The conductive filling layer 238 has a rectangular cross section and is filled within the U-shape of the work function metal layer 236. The top conductive layer 242 is formed over the work function metal layer 236 and the conductive filling layer 238.

Various embodiments or examples described herein offer multiple advantages over the state-of-art technology. For example, embodiments of the present disclosure improve etching rate uniformity and stability during a subsequent gate electrode etch back process, thus avoiding punch through and short circuits between the gate electrode and source/drain contact.

Some embodiments provide a method for forming a semiconductor device, comprising: forming a semiconductor fin; forming a sacrificial gate structure over the semiconductor fin, wherein the sacrificial gate structure comprises a sacrificial gate dielectric layer and a sacrificial gate electrode; forming sidewall spacers on side surfaces of the sacrificial gate structure; recess etching the semiconductor fin on opposing sides of the sacrificial gate structure; forming source/drain regions on the opposing sides of the sacrificial gate structure; depositing a CESL (contact etch stop layer) on the source/drain regions; depositing an ILD (interlayer dielectric) layer on the CESL; removing the sacrificial gate electrode to form a gate cavity; etching back a portion of the sidewall spacers to a first level, wherein the CESL is exposed to the gate cavity; depositing a gate dielectric layer on the CESL exposed to the gate cavity; forming a work function metal layer over the gate dielectric layer; etching back the work function metal layer to a second level; forming a top conductive layer on the work function metal layer; and forming a SAC (self-aligned contact) layer.

Some embodiments provide a method comprising forming a plurality of semiconductor fins along a first direction, wherein the plurality of semiconductor fins extend from a STI (shallow trench isolation) layer; depositing a sacrificial a sacrificial gate dielectric layer over the plurality of semiconductor fins and the STI layer; depositing a sacrificial gate electrode layer on the sacrificial gate dielectric layer; forming a first gate mask and a second gate mask along a second direction on the sacrificial gate electrode layer, wherein the first gate mask has a first gate length along the first direction, the second gate mask has a second gate length along the first direction, and the first gate mask is shorter than the second gate mask; etching the sacrificial gate electrode layer using the first gate mask and the second gate mask to form a first sacrificial gate structure and a second sacrificial gate structure, wherein etching the sacrificial gate electrode layer comprises: generating a plasma from an etching gas and a passivation; and adjusting a ratio of the etching gas and the passivation gas to adjust a profile of the first and second sacrificial gate structure; forming sidewall spacers on side surfaces of the sacrificial gate structure; recess etching the semiconductor fin on opposite sides of the first and second sacrificial gate structures; forming source/drain regions on opposing sides of the first and second sacrificial gate structures; depositing a CESL (contact etch stop layer) on the source/drain regions; depositing an ILD (interlayer dielectric) layer on the CESL; removing the sacrificial gate electrode layer to form a gate cavity; etching back a portion of the sidewall spacers; and forming a first replacement gate structure and a second replacement gate structure after etching back the sidewall spacers.

Some embodiments provide a semiconductor device, comprising: a first semiconductor fin; a first gate structure formed over the semiconductor fin, wherein the first gate structure comprises: first pair of sidewall spacers; a first gate dielectric layer on the first pair of sidewall spacers and the first semiconductor fin; a first work function metal layer formed on the first gate dielectric layer; and a first top conductive layer on the first work function metal layer; a second semiconductor fin; and a second gate structure formed over the second semiconductor fin, wherein the second gate structure comprises: second pair of sidewall spacers; a second gate dielectric layer on the second pair of sidewall spacers and second semiconductor fin; a second work function metal layer on the second gate dielectric layer; a conductive filling layer on the second work function metal layer; and a second top conductive layer on the second work function metal layer and the conductive filling layer.

The following outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device, comprising:
a first semiconductor fin;
a first gate structure formed over the semiconductor fin, wherein the first gate structure comprises:
first pair of sidewall spacers;
a first gate dielectric layer on the first pair of sidewall spacers and the first semiconductor fin;
a first work function metal layer formed on the first gate dielectric layer; and
a first top conductive layer on the first work function metal layer;
a second semiconductor fin; and
a second gate structure formed over the second semiconductor fin, wherein the second gate structure comprises:
second pair of sidewall spacers;
a second gate dielectric layer on the second pair of sidewall spacers and second semiconductor fin;
a second work function metal layer on the second gate dielectric layer;
a conductive filling layer on the second work function metal layer; and
a second top conductive layer on the second work function metal layer and the conductive filling layer.

2. The semiconductor device of claim 1, wherein the second work function layer has a U-shape cross section, the conductive filling layer is inside the U-shape of the second work function layer.

3. The semiconductor device of claim 2, wherein the conductive filling layer has a U-shape cross section, and a dielectric filling layer is disposed inside the U-shape of the conductive filling layer.

4. The semiconductor device of claim 3, wherein the second top conductive layer is disposed around the dielectric filling layer.

5. The semiconductor device of claim 1, further comprising:
a first SAC (self-aligned contact) on the first top conductive feature and above the first pair sidewall spacers.

6. The semiconductor device of claim 1, wherein the first pair of sidewall spacers comprises a low-k material.

7. The semiconductor device of claim 1, wherein the first semiconductor fin and the second semiconductor fin extend along a first direction, the first gate structure has a first length along the first direction, the second gate structure has a second length along the first direction, and the second length is greater than the first length.

8. The semiconductor device of claim 1, wherein the first top conductive layer and the second top conductive layer are formed from the same material.

9. A semiconductor device, comprising:
a semiconductor channel layer; and
a gate structure formed over the semiconductor channel layer, wherein the gate structure comprises:
a pair of sidewall spacers;
a gate dielectric layer on the pair of sidewall spacers and semiconductor channel layer;
a work function metal layer on the gate dielectric layer;
a top conductive layer on the work function metal layer; and
a dielectric filling layer disposed in the top conductive layer.

10. The semiconductor device of claim 9, wherein the dielectric filling layer divides the top conductive layer into two portions.

11. The semiconductor device of claim 10, wherein the work function layer has a U-shape cross section.

12. The semiconductor device of claim 9, further comprising a conductive filling layer disposed on the work function metal layer, wherein the top conductive layer is disposed on the work function metal layer and the conductive filling layer.

13. The semiconductor device of claim 12, wherein the dielectric filling layer is in disposed on the conductive filling layer.

14. The semiconductor device of claim 9, wherein the top conductive layer is disposed around the dielectric filling layer.

15. A semiconductor device, comprising:
a semiconductor channel layer; and
a gate structure formed over the semiconductor channel layer, wherein the gate structure comprises:
a pair of sidewall spacers;
a gate dielectric layer on the pair of sidewall spacers and semiconductor channel layer;
a work function metal layer on the gate dielectric layer, wherein the work function layer has a U-shape cross section;
a conductive filling layer disposed in the work function metal layer; and
a top conductive layer on the work function metal layer.

16. The semiconductor device of claim 15, wherein the conductive filling layer has a U-shape cross section.

17. The semiconductor device of claim 16, further comprising:
a dielectric filling layer disposed on the conductive filling layer.

18. The semiconductor device of claim 17, wherein the dielectric filling layer divides the top conductive layer into two portions.

19. The semiconductor device of claim 17, wherein the top conductive layer is disposed around the dielectric filling layer.

20. The semiconductor device of claim 17, wherein a bottom surface of the dielectric filling material is below the top conductive layer.

9. A method, comprising:
forming a plurality of semiconductor fins along a first direction, wherein the plurality of semiconductor fins extend from a STI (shallow trench isolation) layer;
depositing a sacrificial a sacrificial gate dielectric layer over the plurality of semiconductor fins and the STI layer;
depositing a sacrificial gate electrode layer on the sacrificial gate dielectric layer;
forming a first gate mask and a second gate mask along a second direction on the sacrificial gate electrode layer, wherein the first gate mask has a first gate length along the first direction, the second gate mask has a second gate length along the first direction, and the first gate mask is shorter than the second gate mask;
etching the sacrificial gate electrode layer using the first gate mask and the second gate mask to form a first sacrificial gate structure and a second sacrificial gate structure, wherein etching the sacrificial gate electrode layer comprises:
generating a plasma from an etching gas and a passivation; and
adjusting a ratio of the etching gas and the passivation gas to adjust a profile of the first and second sacrificial gate structure;
forming sidewall spacers on side surfaces of the sacrificial gate structure;
recess etching the semiconductor fin on opposite sides of the first and second sacrificial gate structures;
forming source/drain regions on opposing sides of the first and second sacrificial gate structures;
depositing a CESL (contact etch stop layer) on the source/drain regions;
depositing an ILD (interlayer dielectric) layer on the CESL;
removing the sacrificial gate electrode layer to form a gate cavity;
etching back a portion of the sidewall spacers; and
forming a first replacement gate structure and a second replacement gate structure after etching back the sidewall spacers.

10. The method of claim 9, wherein etching the sacrificial gate electrode layer comprises adjusting the ratio of the etching gas and the passivation gas to generate a straight profile.

11. The method of claim 10, wherein etching the sacrificial gate electrode layer comprises adjusting a plasma power level and/or a bias power level to generate a straight profile.

12. The method of claim 9, wherein the first replacement gate structure comprises:
a gate dielectric layer;
a work function metal layer formed on the gate dielectric layer; and
a top conductive layer formed on the work function metal layer.

13. The method of claim 12, wherein the second replacement gate structure comprises:
a gate dielectric layer;
a work function metal layer formed on the gate dielectric layer;
a conductive filling layer formed on the work function metal layer; and
a top conductive layer formed on the work function metal layer and conductive filling layer.

14. The method of claim 13, wherein the second replacement gate structure further comprises:
a dielectric filling layer disposed on the conductive filling layer, wherein the top conductive layer is in contact with the dielectric filling layer.
